(19) United States
(12) Patent Application Publication
(10) Pub. No.: US 2025/0393161 A1
(43) Pub. Date: Dec. 25, 2025

(54) COOLING SYSTEM

(71) Applicant: CoolIT Systems, Inc., Calgary (CA)

(72) Inventors: Mohammad Reza Najjari, Calgary (CA); Bradley Zakaib, Calgary (CA)

(21) Appl. No.: 19/171,345

(22) Filed: Apr. 6, 2025

Related U.S. Application Data
(63) Continuation-in-part of application No. 19/063,297, filed on Feb. 26, 2025.
(60) Provisional application No. 63/558,645, filed on Feb. 27, 2024.
(60) Provisional application No. 63/575,623, filed on Apr. 6, 2024.
(60) Provisional application No. 63/633,584, filed on Apr. 12, 2024.
(60) Provisional application No. 63/635,593, filed on Apr. 17, 2024.

(51) Int. Cl. H05K 7/20

(52) U.S. Cl. CPC H05K 7/20254; H05K 7/20263; H05K 7/20272

(57) ABSTRACT

A hybrid cold plate can have one or more fluid-cooled cold plates assembled in conjunction with a thermal transfer plate. The fluid-cooled cold plates can cool high heat-flux processing units and the thermal transfer plate can cool adjacent components, which may have lower heat flux, higher temperature thresholds, or both, compared to the processing units. A fluid connection for a fluid-cooled cold plate can include a raised boss with an undercut flange, a fluid connector positioned within the raised boss, and a retainer clip.

### CROSS-REFERENCE TO RELATED APPLICATIONS

This application claims benefit of and priority from U.S. Patent Application No. 63/575,623, filed Apr. 6, 2024, U.S. Patent Application No. 63/633,584, filed Apr. 12, 2024, and U.S. Patent Application No. 63/635,593, filed Apr. 17, 2024, and is a continuation-in-part of co-pending U.S. patent application Ser. No. 19/063,297, filed Feb. 26, 2025, which claims benefit of and priority from U.S. Patent Application No. 63/558,645, filed Feb. 27, 24.

This application and the subject matter disclosed herein (collectively referred to as the “disclosure”) pertain to principles and techniques described in U.S. Pat. No. 8,746,330, issued Jun. 10, 20214, which claims benefit of and priority from U.S. Provisional Patent Application No. 60/954,987, filed Aug. 9, 2007, the contents of which patent and patent application are hereby incorporated by reference to the same extent as if reproduced in full, for all purposes.

### FIELD

This disclosure generally concerns components that facilitate or provide heat transfer between a solid and a liquid, together with associated systems and methods. More particularly, but not exclusively, this disclosure pertains to liquid-and two-phase cooling systems that transfer heat from one or more heat-generating components to a fluid (e.g., in a liquid state, a gaseous state, or a saturated mixture of liquid and gas) passing through a cold plate, or a plurality thereof, each having a plurality of microchannels through which the fluid passes to absorb heat, together with related methods and systems.

### BACKGROUND INFORMATION

New generations of electronic components, such as, for example, memory components, microprocessors, graphics processors, and power electronics semiconductor devices, produce increasing amounts of heat when operating. In addition, electronic devices, such as, for example, servers, computers, game consoles, power electronics, communications and other networking devices, batteries, and so on, arrange electronic components in close proximity with each other. If the heat generated by operating such components is not removed at a sufficient rate, the components can overheat, decreasing their performance, reliability, or both, and in some cases such overheating can result in outright component damage or failure.

The prior art has addressed these challenges using air cooling, liquid cooling (e.g., involving liquid coolant, e.g., water, glycol, polyethylene glycol, etc.), or a combination thereof, to transfer and dissipate heat from electronic components to an ultimate heat sink, e.g., the atmosphere.

Conventional air cooling relies on natural convection or uses forced convection (e.g., a fan mounted near a heat producing component) to replace heated air with cooler ambient air around the component. Such air-cooling techniques can be supplemented with a conventional “heat sink,” which often is a plate of a thermally conductive material (e.g., aluminum or copper) placed in thermal contact with the heat-producing component. The heat sink can spread heat from the component to a larger area for dissipating heat to the surrounding air. Some heat sinks include “fins” to further increase the surface area available for heat transfer and thereby to improve the transfer of heat to the air. Some heat sinks include a fan to force air among the fins and are commonly referred to in the art as “active” heat sinks. Some have previously proposed removing heat from a plurality of heat-generating components arranged in close proximity with each other using a single, air-cooled heat sink.

Liquid cooling improves cooling performance compared to air cooling techniques described above, as many liquids, e.g., water, have significantly better heat transfer capabilities than air. FIG. 1 illustrates various components of a liquid cooling loop 100. The cooling loop 100 typically operates by (1) transferring heat, \dot{Q}ᵢₙ, from a heat-generating electronic component (not shown) to a cool liquid passing through a heat exchanger 110 (sometimes referred to in the art as a “cold plate” or a “heat sink”) placed in thermal contact with the heat-generating component, (2) transporting the heat absorbed by the liquid to a remote radiator 120, or heat rejector (sometimes referred to in the art generally as a “heat exchanger,” or a “liquid-to-liquid heat exchanger” if the heat is rejected to another liquid or a “liquid-to-air heat exchanger” if the heat is rejected to air), (3) dissipating the heat, \dot{Q}ₒᵤₜ, from the remote radiator to another medium (e.g., air or facility water passing through the remote radiator), and (4) returning cooled liquid to the heat exchanger (or heat sink).

### SUMMARY

Presently disclosed cooling devices and systems provide further improved cooling performance compared to previously proposed cooling devices and systems. For example, in contrast to previously proposed techniques that provide a large, single-mode heat sink (or cold plate) placed in thermal contact with a plurality of closely arranged heat-generating components, disclosed hybrid cold plates combine, for example, one or more liquid-or a refrigerant-cooled cold plate with a fluid network comprising a plurality of conduits and fluid connections that convey a flow of the fluid (sometimes referred to in the art as a “coolant” or a “refrigerant,” though “refrigerant” often, but not always, refers to a two-phase coolant within a vapor-compression system).

According to an aspect, for example, a cold plate can have an inlet, an outlet, and a passageway configured to convey a fluid from the inlet to the outlet. Such a cold plate has a housing wall having an internal surface defining a boundary of the passageway and an external surface. A raised boss extends from the external surface of the housing wall to an upper surface. The upper surface of the raised boss defines an aperture. The raised boss and housing wall define a through-hole recess extending from the aperture in the upper surface of the raised boss to an opposed opening through the boundary of the passageway defined by the housing wall. The raised boss defines a peripheral wall extending around the through-hole recess. The peripheral wall has an inner surface corresponding to the through-hole recess and outer peripheral surface. The raised boss defines an undercut slot positioned between the external surface of the housing wall and the upper surface of the raised boss. The undercut slot defines an opening extending from the outer peripheral surface to the through-hole recess.

The undercut slot can be a first undercut slot. For example, the raised boss can also define a second undercut slot defining an opening extending from the outer peripheral surface to the through-hole recess.

In some embodiments, a portion of the peripheral wall of the raised boss extends from the first undercut slot to the second undercut slot, providing a solid boundary of the through-hole recess positioned between the first undercut slot to the second undercut slot.

The undercut slot can be positioned distally of the upper surface of the raised boss.

The through-hole recess can define a proximal portion positioned adjacent the aperture in the upper surface of the raised boss to a distal portion positioned adjacent the opening through the boundary of the passageway. The proximal portion of the through-hole recess can defines a fluted periphery having a fluted region.

In some embodiments, the fluted region is defined by a radial enlargement of the through-hole recess extending through an arcuate segment of the periphery of the through-hole recess. In some such embodiments, the undercut slot extends from the outer peripheral surface to the fluted region.

In some embodiments, the fluted region is a first fluted region and the fluted periphery can have a plurality of fluted regions. For example, the fluted region can be a first fluted region and the fluted periphery can have four fluted regions.

The through-hole recess can define a first shoulder positioned distally of the fluted periphery. In some embodiment, the through-hole recess can define a second shoulder positioned distally of the first shoulder and proximally of the opening through the boundary of the passageway defined by the housing wall.

The through-hole recess can define a longitudinal axis extending from the aperture in the upper surface of the raised boss to an opposed opening through the boundary of the passageway defined by the housing wall. The cold plate can also include a spring clip having a leg configured to extend through the undercut slot transversely relative an axis parallel to the longitudinal axis. Some such cold plate embodiments also include fluid connector having an external surface so complementarily shaped relative to the through-hole recess as to be matingly receivable by the through-hole recess.

For example, the fluid connector can define a distal piston and an annular ring extending circumferentially around the piston proximally positioned of the distal piston.

The annular ring can be a first annular ring and the fluid connector can also define a second annular ring positioned proximally of and spaced apart from the first annular ring, defining an annular gap positioned therebetween.

Some cold plate embodiments also have an O-ring extending around the piston at a position distally of the first annular ring. The annular gap can align with the opening defined by the undercut slot when the fluid connector and O-ring are seated within the through-hole recess. The leg of the spring clip can extend through the opening defined by the undercut slot and through the annular gap defined by the fluid connector, retaining the fluid connector within the recessed through-hold aperture.

The spring clip can be a U-shaped spring clip configured to capture the fluid connector within the raised boss defined by the cold plate housing.

According to another aspect, a cooling system has a cold plate configured to be placed into thermal contact with a heat-generating component and to facilitate a transfer of heat from the heat-generating component to a fluid passing through the cold plate. Such a cooling system also has a heat-exchanger configured to reject heat from the fluid to another medium. The cooling system also includes a fluid circuit configured to so circulate the fluid through the cooling system as to convey fluid heated in the cold plate to the heat-exchanger and to convey fluid cooled in the heat-exchanger to the cold plate. The cold plate defines one or more fluid connections for coupling the cold plate with the fluid circuit. At least one of the one or more fluid connections has a raised boss, a fluid connector and a retainer clip. The raised boss defines an internal bore, an outer peripheral surface, and an undercut slot extending from the outer peripheral surface to the internal bore. The fluid connector has a distal portion positioned within the internal bore and a proximal portion extending from the raised boss. The fluid connector defines an external surface having an annular recess aligned with the undercut slot, a shoulder positioned distally of the annular recess and an O-ring positioned distally of the shoulder. The retainer clip has an arm extending through the undercut slot and within the annular recess of the fluid connector to capture the distal portion of the fluid connector within the internal bore.

The internal bore can define a proximal region having a fluted periphery defining a plurality of fluted regions circumferentially spaced apart from each other. The undercut slot can be a first undercut slot that extends from the outer peripheral surface of the raised boss to one of the fluted regions. The raised boss can also define a second undercut slot that extends from the outer peripheral surface of the raised boss to a second one of the fluted regions.

The retainer clip can be a U-shaped clip having a pair of spaced-apart arms. At least one of the spaced-apart arms can be so sized to extend from external to the peripheral wall through the first undercut slot and the second undercut slot.

The at least one of the spaced-apart arms can define an inner edge positioned adjacent the external surface of the fluid connector. The inner edge can have a detente region so configured to urge against the external surface of the fluid connector as to inhibit the U-shaped clip from backing out of the first undercut slot and the second undercut slot.

The foregoing and other features and advantages will become more apparent from the following detailed description, which proceeds with reference to the accompanying drawings.

### BRIEF DESCRIPTION OF THE DRAWINGS

Referring to the drawings, wherein like numerals refer to like parts throughout the several views and this specification, aspects of presently disclosed principles are illustrated by way of example, and not by way of limitation.

FIG. 1 schematically illustrates a closed liquid-cooling loop.

FIG. 2 schematically illustrates a hybrid cold plate having a plurality of cold plates and a thermal transfer plate.

FIG. 3 illustrates an isometric view of a hybrid cold plate as in FIG. 2.

FIG. 4 illustrates a plan view from above the hybrid cold plate shown in FIG. 2.

FIG. 5 illustrates a plan view from below the hybrid cold plate shown in FIG. 2.

FIG. 6 shows a portion of the hybrid cold plate shown in FIG. 2.

FIG. 7 shows an enlarged view of the portion of the hybrid cold plate shown in FIG. 6.

FIG. 8 shows a representative fluid connector.

FIG. 9 shows a representative clip for retaining a fluid connector as in FIG. 8 within a cold plate port, e.g., a cold plate as in FIG. 2.

FIG. 10 shows an isometric drawing of one of the cold plates shown in FIG. 2.

FIG. 11 shows a plan view from above a section taken through the cold plate shown in FIG. 10. The section is taken below the raised bosses shown in FIG. 10.

FIG. 12 shows another plan view from above a section taken through a plane below the section shown in FIG. 11.

FIG. 13 shows another plan view from above a section taken through a plane below the section shown in FIG. 12.

FIG. 14 shows an isometric drawing of one of the cold plates shown in FIG. 2.

FIG. 15 shows an isometric drawing of one of the cold plates shown in FIG. 2.

FIG. 16 shows an isometric drawing from above a section taken through the raised bosses and within the undercut slot shown in FIG. 15.

FIG. 17 shows an isometric drawing from above a section taken through a plane below the section shown in FIG. 16.

FIG. 18 shows an isometric drawing from above a section taken through a plane below the section shown in FIG. 17.

\

FIG. 19 shows an isometric view from above a plan section through the hybrid cold plate shown in FIG. 3 to reveal the retainer clips that capture the fluid connectors within the several raised bosses.

FIG. 20 shows an isometric view from above another plan section through the hybrid cold plate shown in FIG. 3 taken below the plane in FIG. 19 to reveal various segments of the fluid passages through the hybrid cold plate, similar to the schematic illustration in FIG. 2.

FIG. 21 shows an isometric view from above another plan section through the hybrid cold plate shown in FIG. 3 taken below the plane in FIG. 20 to reveal various segments of the fluid passages through the hybrid cold plate similar to the schematic illustration in FIG. 2.

FIG. 22 shows an embodiment of a flow network through a hybrid cold plate as depicted above.

FIG. 23 shows another embodiment of a flow network through a hybrid cold plate as depicted above.

FIG. 24 shows another embodiment of a flow network through a hybrid cold plate as depicted above.

FIG. 25 shows another embodiment of a flow network through a hybrid cold plate as depicted above.

FIG. 26 shows an isometric view of a base plate embodiment suitable for use with a disclosed cold plate.

FIG. 27 shows an isometric view of a section of the base plate shown in FIG. 26.

FIG. 28 shows an end-elevation of the section shown in FIG. 27.

FIG. 29 shows an isometric view from below of a manifold plate embodiment suitable for use with a disclosed cold plate.

FIG. 30 shows a plan view from below the manifold plate shown in FIG. 29.

FIG. 31 shows an isometric view from above the manifold plate shown in FIG. 29.

FIG. 32 shows a plan view from above the manifold plate shown in FIG. 29.

FIG. 33 shows an isometric view of a section of the manifold plate shown in FIG. 30.

FIG. 34 shows an isometric view from above a top plate embodiment suitable for use with a disclosed cold plate.

FIG. 35 shows a side-elevation view of the top plate shown in FIG. 35.

FIG. 36 shows an isometric view from below the top late shown in FIG. 34.

FIG. 37 shows the isometric view in FIG. 36 with annotations to depict an interface between the lower surface of the top plate and the upper surface of the manifold plate shown in FIG. 29.

FIG. 38 shows an exploded, isometric view from above a cold plate having a base plate as in FIG. 26, a manifold plate as in FIG. 30 and a top plate as in FIG. 34.

FIG. 39 shows an isometric view from below the exploded cold plate shown in FIG. 38.

FIG. 40 shows an isometric view from above a fluid connection in a housing wall.

FIG. 41 shows an exploded isometric view from above the fluid connection shown in FIG. 40.

FIG. 42 shows an isometric view from above a section of the fluid connection shown in FIG. 40 taken along line 42-42.

FIG. 43 shows an isometric view from above a section of the fluid connection shown in FIG. 40 taken along line 43-443.

FIG. 44 shows an isometric view from above a section of the fluid connection shown in FIG. 40 taken along line 44-44.

FIG. 45 shows an isometric view from above a fluid connector of the type used in the fluid connection shown in FIG. 40.

FIG. 46 shows a line drawing of a side-elevation view of the fluid connector shown in FIG. 45.

FIG. 47 shows an isometric view from above an exposed fluid connection as in FIG. 42, with the housing wall removed to review the internal assembly of the fluid connection.

FIG. 48 shows a side elevation view of the exposed fluid connection shown in FIG. 47.

FIG. 49 shows an isometric view of a spring clip used in the fluid connection shown in FIG. 42.

FIG. 50 shows an isometric view from above the housing wall shown in FIG. 40.

FIG. 51 shows a plan view from above the housing wall shown in FIG. 40.

FIG. 52 shows a side-elevation view of the housing wall shown in FIGS. 40 and 50.

FIG. 53 shows an end-elevation view of the housing wall shown in FIGS. 40, 50 and 52.

### DETAILED DESCRIPTION

The following describes various principles related to heat-transfer components. For example, certain aspects of disclosed principles pertain to cold plates for cooling heat-generating electronic components using liquid-or two-phase cooling systems. That said, descriptions herein of specific apparatus configurations and combinations of method acts are but particular examples of contemplated systems chosen as being convenient illustrative examples of disclosed principles. One or more of the disclosed principles can be incorporated in various other systems to achieve any of a variety of corresponding system characteristics.

Thus, systems having attributes that are different from those specific examples discussed herein can embody one or more presently disclosed principles, and can be used in applications not described herein in detail. Accordingly, such alternative embodiments also fall within the scope of this disclosure.

A thermal transfer plate 210 (sometimes referred to as a “TTP”) defines a heat transfer surface (or a plurality of heat-transfer surfaces) that absorb heat from one or more heat sources, while also defining an internal manifold 211 for distributing coolant (or refrigerant) between or among a plurality of cold plates. Such a hybrid cold plate 200 can have a significantly lower mass compared to a large heat sink while effectively cooling a plurality of closely arranged heat-generating components, including, for example, processing units (e.g., graphics processing units (GPUs), central processing units (CPUs), power electronics devices (e.g., voltage regulators, capacitors, etc.), communication bridges (or chipsets), and memory devices.

The hybrid cold plate 200 provides a liquid-or a refrigerant-cooled cold plate (e.g., cold plates 220, 230, 240) for (1) directly cooling one or more, e.g., high-power, low-temperature (or both), heat-generating components; and (2) indirectly cooling one or more other, e.g., relatively-lower power, higher-temperature (or both), heat-generating components. For example, such a hybrid cold plate 200 can include a thermal-transfer plate 210 to transfer heat from one or more heat-generating components to the coolant passing through the thermal-transfer plate, while also distributing the coolant, after absorbing heat from the lower power components, between or among a plurality of cold plates 220, 230, 240 (e.g., incorporating a split-flow technology as in U.S. Pat. No. 8,746,330, or providing a single-pass through a plurality of microchannels, e.g., from one end of the microchannels to an opposed, second end of the microchannels).

For example, cool fluid enters the thermal transfer plate 210 at an inlet 212 and the manifold 211 distributes the fluid to the outlets 213. Conduits 214 convey the fluid heated by the thermal transfer plate 210 to inlets 231, 241 of the cold plates 230, 240, respectively. After passing through the cold plates 230, 240, fluid heated by respective heat-generating components (e.g., GPUs) passes out of the cold plate outlets 232, 242, respectively. Conduits 235 convey the fluid to the inlets 221 to the cold plate 220, where the coolant absorbs heat from another heat-generating component (e.g., a CPU) and exhausts through an outlet 222.

In some embodiments, the thermal transfer plate 210 includes a thermally conductive solid that interfaces (e.g., that is placed into thermal contact with) a heat-exchanging manifold 211. In such embodiments, the thermal transfer plate conveys heat from the one or more heat-generating components through a thermally conductive solid to the heat-exchanging manifold 211. The heat-exchanging manifold 211, in turn, can absorb heat from the thermal transfer plate (e.g., via conduction heat transfer) and transfer to the liquid or refrigerant (e.g., via convective heat transfer) passing through the heat-exchanging manifold. In such an embodiment, the heat exchanging manifold defines an internal flow passage (e.g., a single pass over a flat internal surface, or one or more passes of coolant over a plurality of extended heat transfer surfaces, e.g., through macro- or microchannels defined by a plurality of fins or other porous or semiporous structure) that promotes convective heat transfer between the coolant and the solid body of the heat-exchanging manifold. Further, the internal flow passage can define a single passageway from an inlet 212 to one or more outlets 213, or the internal flow passage can define a complex network of passageways from the inlet to a plurality of outlets. The internal flow passage can be configured to provide an equal portion of the incoming flow of coolant to each outlet 213 from the heat-exchanging manifold, or the internal flow passage can be configured to provide a selected portion of the incoming flow of coolant to each outlet, e.g., an unequal distribution of flow portions according to anticipated cooling demand for each cold plate or other heat-transfer device fluidically coupled with the respective outlet from the heat-exchanging manifold. Each portion of flow through the one or more outlets 213 can correspond to an anticipated cooling demand downstream of the outlet, as well as an anticipated or expect rise in temperature of coolant through the heat-exchanging manifold from the inlet to the respective outlet.

In an embodiment, such a thermally conductive solid can span across one or more components and facilitate heat transfer from the one or more components to a liquid-cooling loop (or a two-phase cooling loop), a portion of which passes through the heat-exchanging manifold. By way of further example, the thermally conductive solid can conduct heat from the one or more heat-generating components to an internally cooled cold plate, which in turn can facilitate a transfer of the heat to a single-or a two-phase coolant passing through the cold plate.

Such thermal transfer plates, or heat exchanging manifolds, can span across one or more components and facilitate heat transfer from the one or more components to a liquid-cooling loop (or a two-phase cooling loop). By way of further example, thermal transfer plate 210 can convey heat from the one or more heat-generating components to an internally cooled cold plate (e.g., another embodiment of a heat-exchanging manifold, which also absorbs heat directly from a component to be cooled), which in turn can facilitate a transfer of the heat to a single- or a two-phase coolant passing through the internally cooled cold plate.

As a further illustrative example, a thermal transfer plate 210 can incorporate one or more passive, two-phase cold plates, e.g., vapor-chamber cold plates, heat-pipe cold plates, etc., which in turn can thermally couple with (e.g., conductively) one or more heat-generating components positioned near, for example, a processing unit. Similarly, a cold plate fluidly coupled with a single-phase or a two-phase cooling loop can be thermally coupled with (e.g., a conductively coupled with) the processing unit, and heat generated by the processing unit can be transferred to the coolant circulating through the cooling loop. Further, the one or more passive, two-phase cold plates can be thermally coupled with (e.g., conductively) the cold plate fluidly coupled with the single-phase or two-phase cooling loop, enhancing cooling of the one or more heat-generating components by transferring heat from those components to the cold plate, and thereby to a coolant flowing through the cooling loop.

An interface between each disclosed cold plate (including the thermal transfer plate) and a corresponding heat-generating component can incorporate a thermal interface material, e.g., to enhance thermal contact between the opposed surfaces of the cold plate and the heat-generating component. Thermal interface materials described herein can include thermal greases, thermal gap pads, thermal gels, thermal interface foils, etc. To facilitate variability in vertical height, e.g., from aggregated manufacturing tolerances, some thermal interface materials will desirably be able to compress to a greater degree than other thermal interfaces.

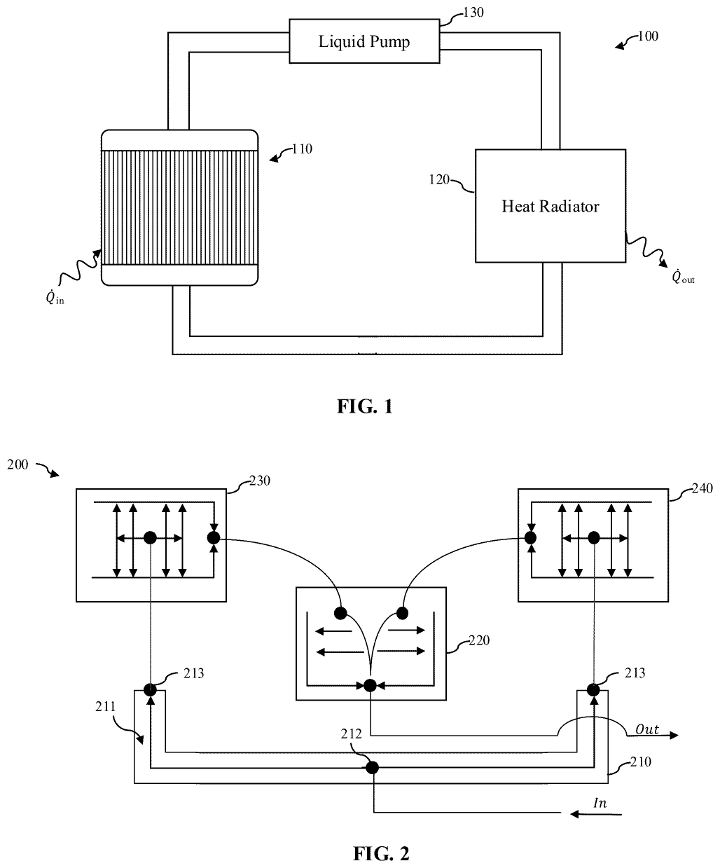

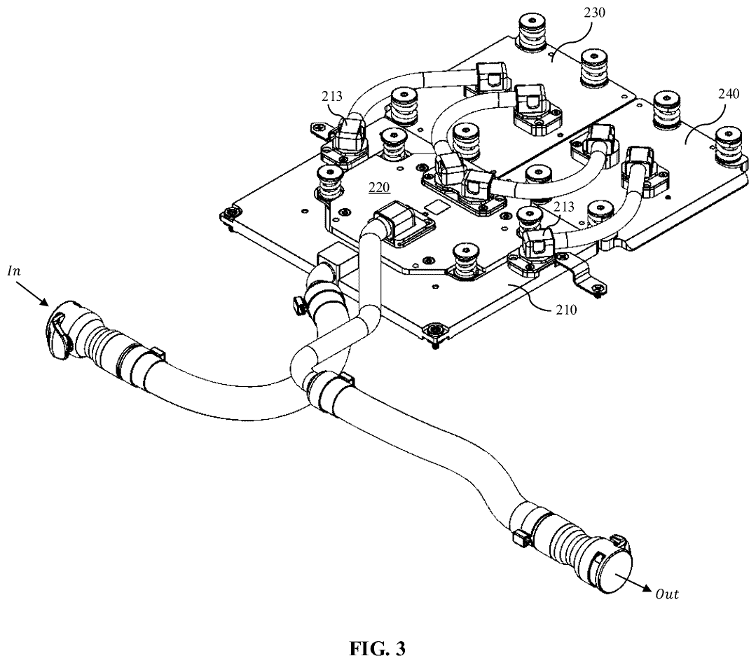

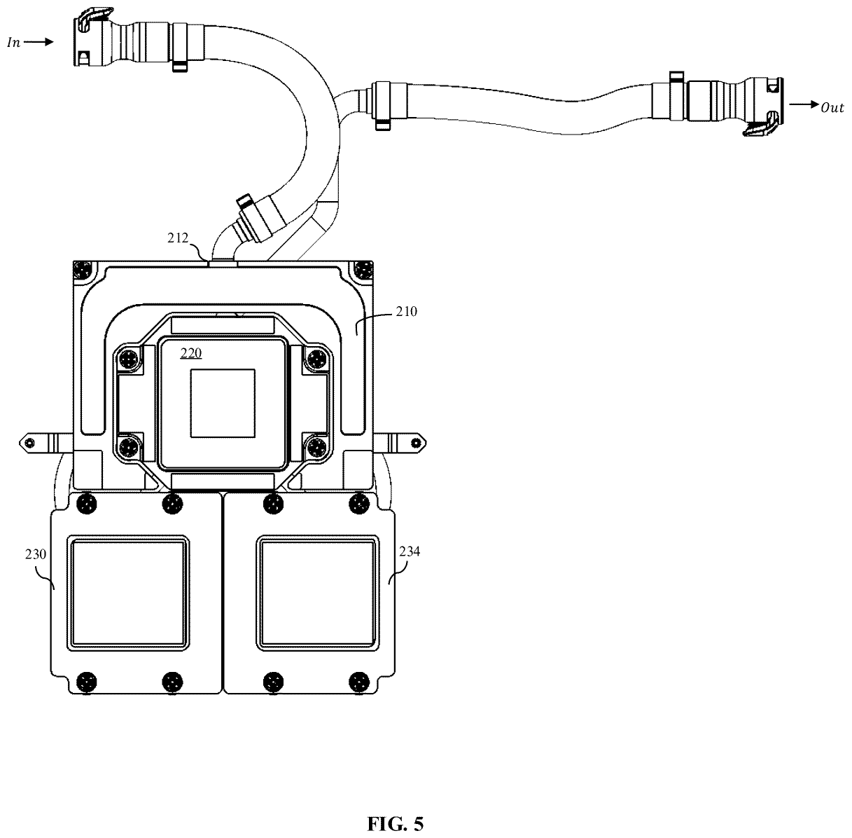

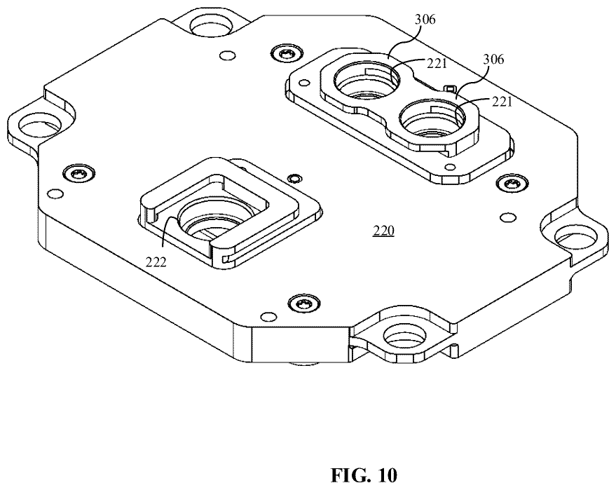

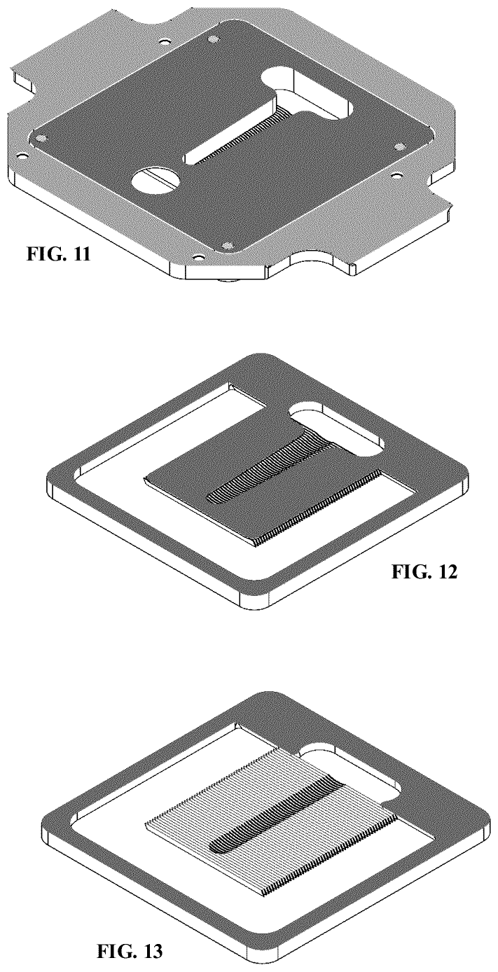

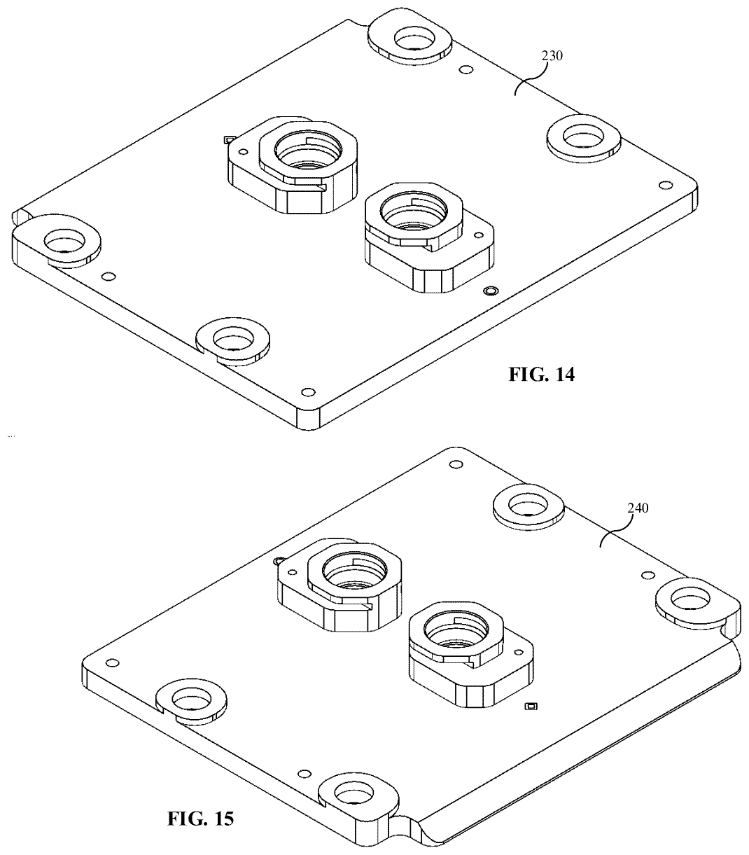

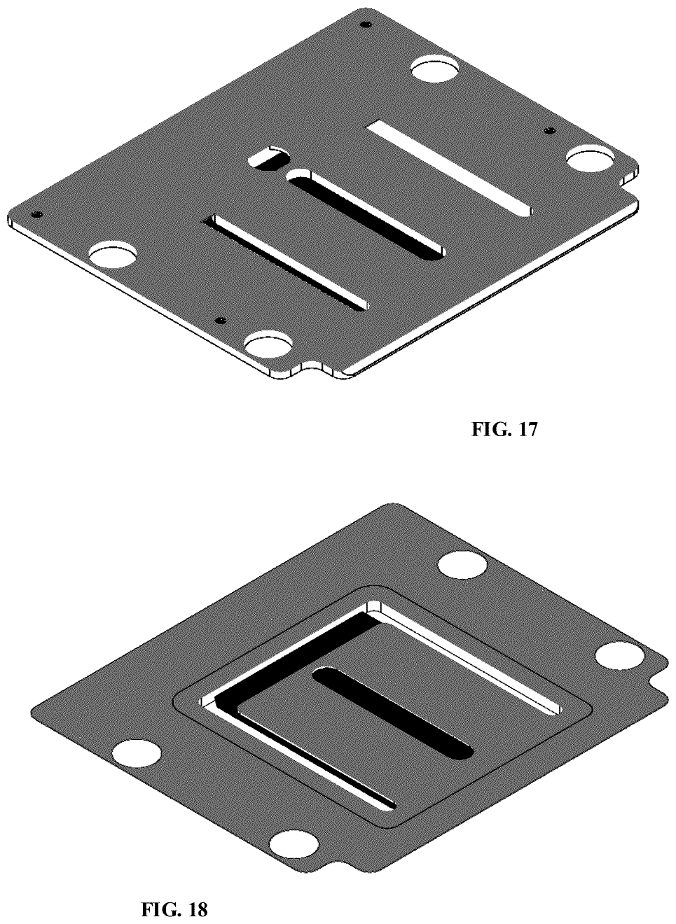

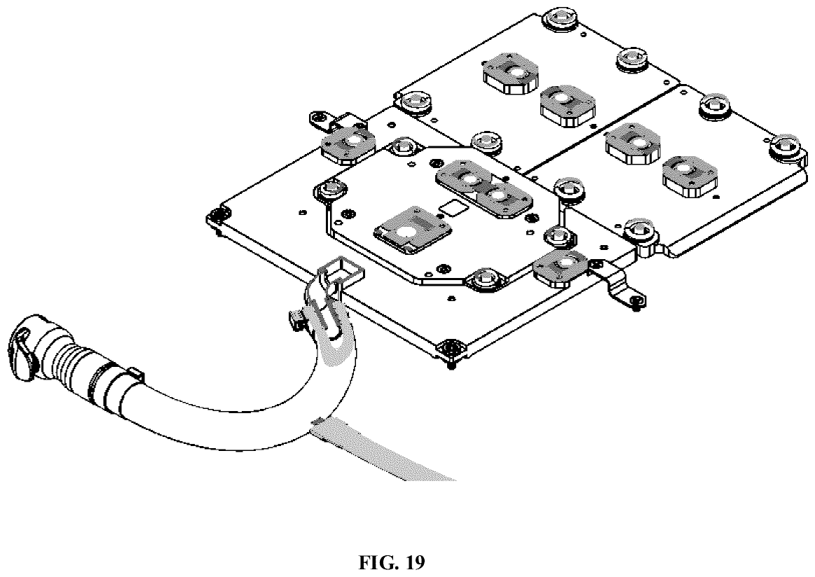

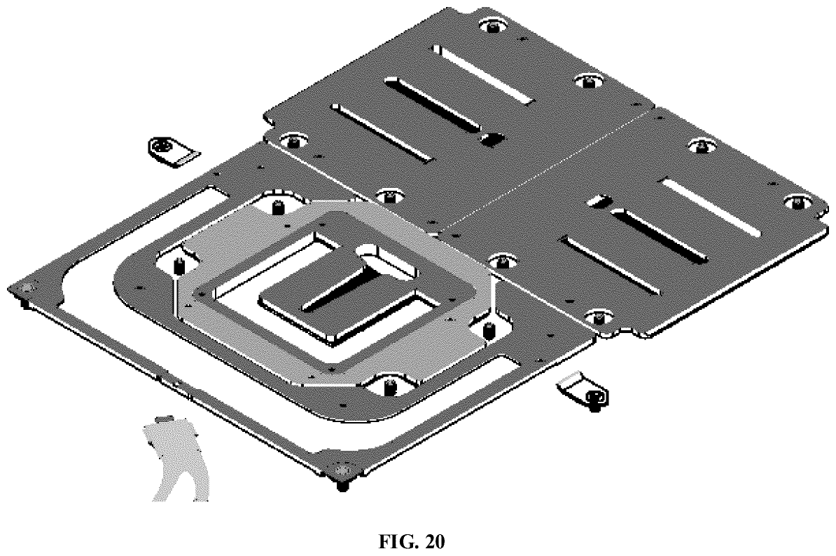

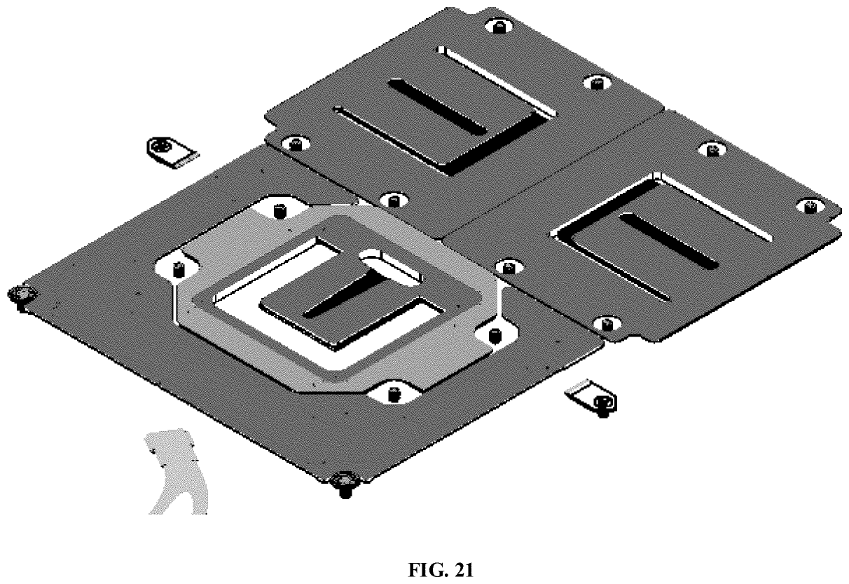

Referring again to the schematic illustration in FIG. 1, an assembly of one or more cold plates and a thermal transfer plate, e.g., as shown among FIGS. 2 to 21, can be substituted for the heat exchanger 110. Alternatively, an assembly of one or more cold plates and a thermal transfer plate, e.g., as shown among FIGS. 2 to 21, can be added to a cooling loop of the type depicted in FIG. 1. For example, the heat exchanger 110 shown in FIG. 1 may be placed in thermal contact with a processing component, and an assembly of one or more cold plates and a thermal transfer plate, e.g., as shown among FIGS. 2 to 21, can be fluidically coupled (in series or in parallel) with the heat exchanger 110. On reviewing this disclosure, a person of ordinary skill in the art will understand and appreciate the various modifications to fluid connections, pumping resources, and radiator configurations that such alternative arrangements could or would require in order to urge a sufficient flow of coolant through each heat exchanger/heat-exchanger assembly in a given cooling loop, as well as to reject absorbed heat from the coolant to another cooling medium.

Such cooling systems also can include a heat radiator 120 configured to reject heat from the liquid coolant to another medium as the liquid coolant passes through the heat radiator, generally as described above in connection with FIG. 1. Such cooling systems also include a pump 130 configured to urge the liquid coolant throughout a closed loop.

A cooling system as just described can be installed in or on an electronic device to cool a multi-chip module, or another plurality of heat-generating components operably assembled with a motherboard or an add-in card, alone or in combination with other heat-generating components e.g., memory components, memory controllers, processing units, power delivery devices, EEPROMs, etc. Moreover, a given electronic device, e.g., a server or a rack of servers, may have a plurality of motherboards, add-in cards, or modules, having operably mounted therewith a plurality of such heat-generating components, with each motherboards, add-in cards, or modules being cooled by an assembly of cold plates and thermal transfer plate as shown among FIGS. 2 to 21.

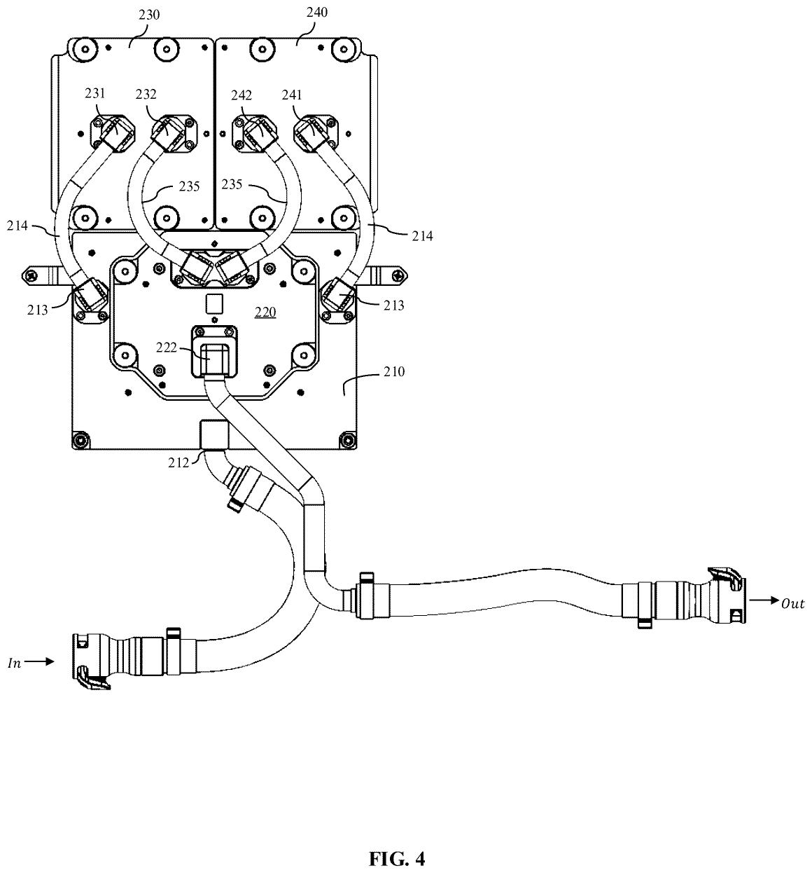

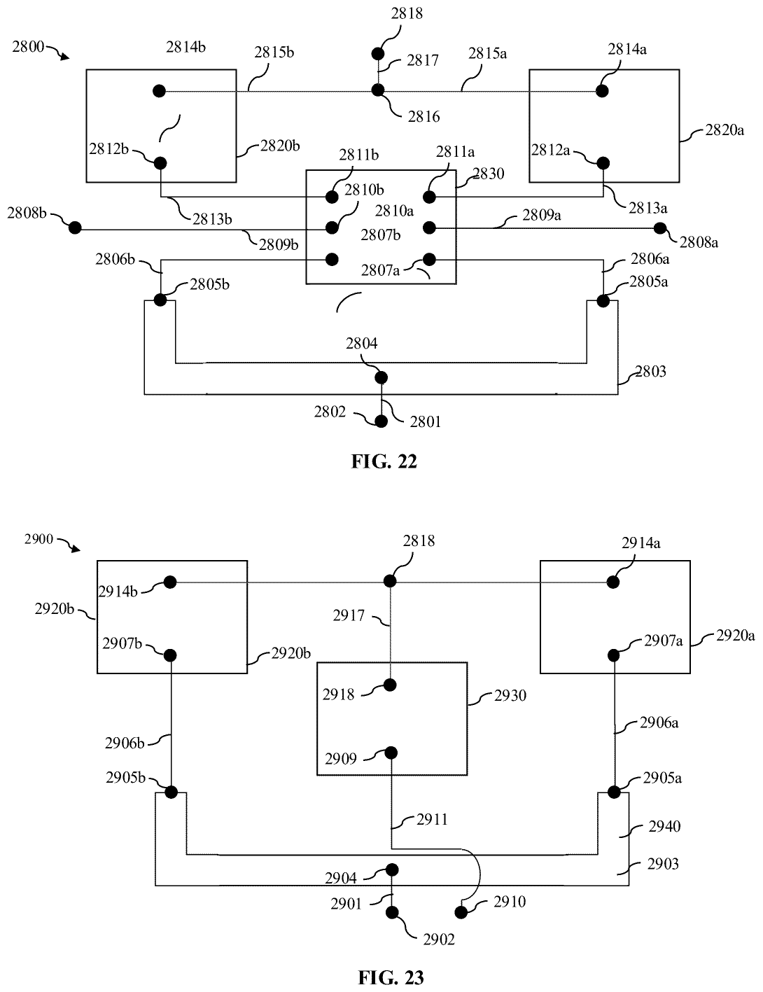

Referring now to FIGS. 22 to 25, several representative embodiments of fluid network arrangements (e.g., relative to the fluid network shown in, for example, FIGS. 2 to 4) are shown and described. As the annotations to FIG. 4 indicate, each cold plate shown among the various drawings herein can be arranged to provide a bifurcated flow through its microchannels, a convergent flow (e.g., opposite flow direction relative to a bifurcated flow) through its microchannels, a multi-inlet-multi-outlet arrangement through its microchannels or a single-pass or a multi-pass flow arrangement through its microchannels.

Turning now to FIG. 22, the fluid network through the hybrid cold plate 2800 has a fluid conduit 2801 extending to a node (or a coupler) 2804, e.g., a turret as shown in FIG. 8, configured to couple a passage through the conduit 2801 to a passage through the internal manifold (e.g., a heat-exchanging manifold) 2840 through the thermal transfer plate 2803. The nodes 2805a, b (and the remaining nodes shown among FIGS. 22 to 25) can be configured similarly to the turret shown in FIG. 8 or any other suitable fluid coupler configured to couple a conduit to a cold plate or other heat-exchanging device. A conduit 2806a, b extends from each node 2805a, b to a node 2807a, b, respectively.

As with the CPU cold plate shown in FIGS. 2 to 4, the cold plate 2830 can be thermally coupled with a heat-generating central processing unit (CPU) or another heat-generating electronic component. The cold plate 2830 is shown with nodes 2811a, b and nodes 2810a, b. Each node 2810a, b is fluidically coupled with a corresponding one of the nodes 2808a, b, and a conduit 2809a, b extends therebetween, respectively. The cold plate 2830 further includes nodes 2811a, b, which are coupled with corresponding nodes 2812a, b of the respective GPU cold plates 2820a, b by way of respective conduits 2813a, 2813b.

The GPU cold plates 2820a, b include respective nodes 2814a, b, which in turn are fluidically coupled with a mixing node (e.g., a combiner or a plumbing “t” joint) 2816 by way of respective conduits 2815a, b. The mixing node 2816 is fluidically coupled with a node 2818 by way of conduit 2817.

In the illustrated embodiment, each of nodes 2802, 2818 and 2808a, b is shown as being disconnected from another device. But as shown in FIG. 1, each of the nodes 2802, 2818 and 2808a, b can be fluidically coupled with another component, e.g., a pump, a heat exchanger (e.g., a radiator), or another cold plate, or with selected ones of each other. For example, the node 2802 can be an inlet to the hybrid cold plate 2800 (e.g., that receives relatively cooler coolant) or it can be an outlet from the hybrid cold plate (e.g., that exhausts relatively warmer coolant). Similarly, the node 2818 can be an inlet to the hybrid cold plate 2800 (e.g., that receives relatively cooler coolant) or it can be an outlet from the hybrid cold plate (e.g., that exhausts relatively warmer coolant). Nevertheless, as a person of ordinary skill in the art will understand following a review of this disclosure, to maintain continuity (e.g., to observe conservation of mass principles), if the nodes 2818 and 2802 are inlets, then one or both of nodes 2808a, b need to define an outlet from the hybrid cold plate 2800, or if the nodes 2818 and 2802 are outlets, then one or both of nodes 2808a, b need to define an inlet to the hybrid cold plate 2800.

In some embodiments, the nodes 2808a, b and 2818 are fluidically coupled with each other. In such embodiments, the nodes 2808a, b and 2818 can define an inlet to the hybrid cold plate 2800 and the node 2802 can define an outlet from the hybrid cold plate 2800. Alternatively, the nodes 2808a, b and 2818 can define an outlet from the hybrid cold plate 2800 and the node 2802 can define an inlet to the hybrid cold plate 2800. In either of the immediately foregoing embodiments, the CPU cold plate can provide an internal manifold configured to collect coolant from one or more of the nodes 2806a, b, 2808a, b, and 2810a, b, to distribute coolant to one or more of the nodes 2806a, b, 2808a, b, and 2810a, b, or any combination thereof. Similarly, the heat-exchanging manifold 2803 can be a distribution or a collection manifold, according to the direction of flow through the manifold 2840.

Referring now to FIG. 23, the hybrid cold plate 2900 has a conduit 2901 coupling the node 2902 with the node 2904 of the internal manifold (e.g., a heat-exchanging manifold) 2940 through the thermal transfer plate 2903. Nodes 2905a, b are coupled with nodes 2907a, b of the GPU cold-plates 2920a, b via respective conduits 2906a, b. The GPU cold plates 2920a, b have respective nodes 2914a, b coupled with a t-connection 2916, which in turn is coupled with a node 2918 of the CPU cold plate 2930 via conduit 2917. The node 2909 of the CPU cold plate is fluidically coupled with the terminal node 2910 via conduit 2911.

The terminal conduit 2911 can be an inlet or an outlet to or from, respectively, the hybrid cold plate 2900. Similarly, the terminal conduit 2902 can be an inlet or an outlet to or from, respectively, the hybrid cold plate 2900. Whether a selected one of the terminal conduits 2902, 2910 is an inlet or an outlet corresponds to whether the other of the terminal conduits 2902, 2910 is an inlet or an outlet, i.e., if one is an inlet the other is an outlet and vice-versa.

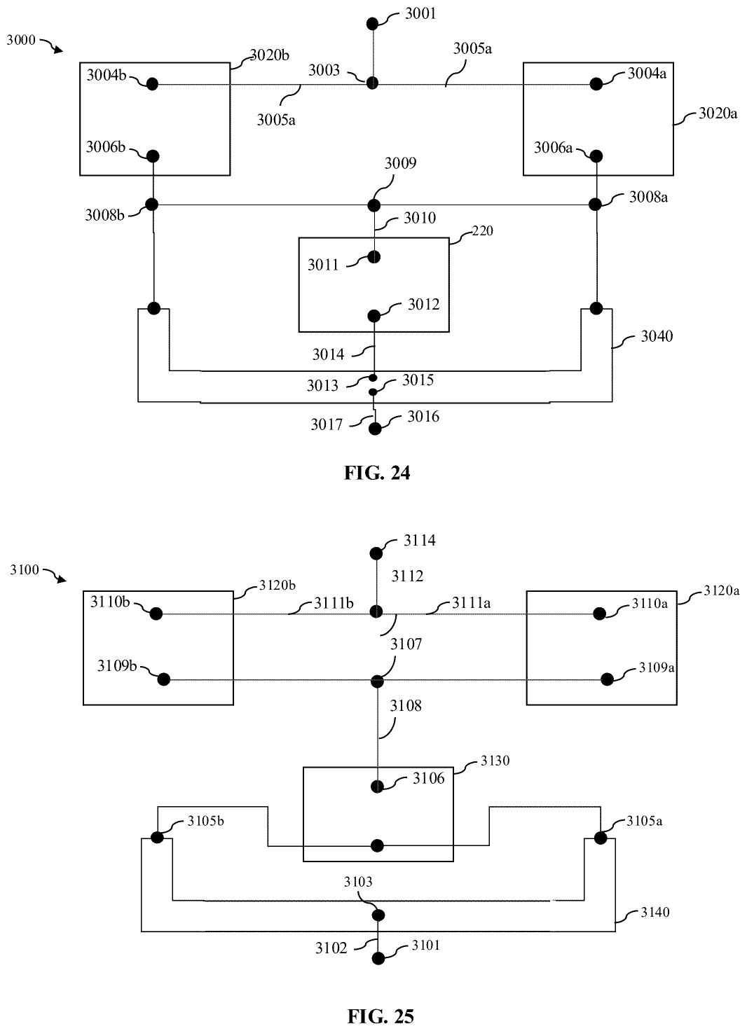

Referring now to FIG. 24, yet another embodiment of a fluid network through a hybrid cold plate 3000 is shown and described. The hybrid cold plate 3000 has a terminal node 3001 fluidically coupled with a “t”-joint 3002, which in turn is coupled with nodes 3004a, b of the respective GPU cold plates 3020a, b by way of respective conduits 3005a, b. Each of nodes 3006a, b of the respective GPU cold plates 3020a, b is fluidically coupled with a “t”-joint 3008a, b, and optionally with a respective node coupled with the heat-exchanging manifold 3040. As well, each “t”-joing 3008a, b fluidcally couples with another “t”-joint 3009 to convey coolant to a node 3011 (by way of conduit 3010) of the CPU cold plate 3030. The node 3014 of the CPU cold plate 3030 fluidically couples with the node 3013 of the heat-exchanging manifold 3040, which further includes a node 3015 coupled with the terminal node 3016 by way of conduit 3017. With an arrangement as in FIG. 24, the GPU cold plates are coupld with each other in parallel and with the CPU cold plate 3030 and the heat-exchanging manifold 3040 in series. With the optional connection between the “t”-joints 3008a, b and the heat-exchanging manifold 3040, the CPU cold plate and the heat-exchanging manifold 3040 are coupled with each other in parallel, and in series with each other by way of the conduit 3013. As with the embodiments above, coolant can flow through the hybrid cold plate 3000 in either direction from one terminal node 3001, 3016 to the other.

In still another embodiment, as shown in FIG. 25, the GPU cold plates 3120a, b can be coupled with each other in parallel, as in the embodiments above, and the GPU cold plates 3120a, b can be coupled in series with the CPU cold plate 3130, which in turn can be coupled in series with the heat-exchanging manifold 3140. A plurality of nodes of the heat-exchanging manifold, e.g., nodes 3015a, b, can be coupled with each other in parallel upstream or downstream of the CPU cold plate 3130, as shown. For example, a terminal node 3101 can be coupled with the heat-exchanging manifold via node 3103 by way of conduit 3102. The nodes 3105a, b of the heat-exchanging manifold can couple with a node of the CPU cold plate 3130, and a node 3106 of the CPU cold plate can couple via conduit 3108 with a “t”-joint 3107, which in turn can couple with a node 3109a, b of the respective GPU cold plates 3120a, b. Nodes 3110a, b of the GPU cold plates 3120a, b can couple via conduits 3111a, b with a “t”-joint 3112, which in turn couples with a terminal node 3114 via conduit 3113. In such an embodiment, either terminal node 3101 or terminal node 3114 can be an inlet or an outlet in accordance with whether the other of the terminal nodes 3101, 3114 is an inlet or an outlet.

Although particular embodiments of fluid network connections have been shown and described, those of ordinary skill in the art following a review of this disclosure will understand and appreciate that any pair of components among each GPU cold plate, CPU cold plate and heat-exchanging manifold in any of these embodiments can be fluidically coupled with each other in series or in parallel to define a hybrid cold plate, and that such a hybrid cold plate falls within the four corners of the present disclosure. For example, although the embodiments above fluidically couple the GPU cold plates in parallel with each other, the GPU cold plates can be fluidically coupled with each other in series. Moreover, although the foregoing embodiments of hybrid cold plates are configured to cool two GPUs (e.g., each GPU cold plate), one CPU (e.g., the CPU cold plate) and one or more other nearby components (e.g., components in thermal contact with the thermal transfer plate or a heat-exchanging manifold, or both), this description is not so limited. Rather, principles disclosed herein can be adopted to cool any selected number of one or more GPUs, CPUs and other heat-generating components. For example, a hybrid cold plate based on this disclosure can be configured to cool any number of GPUs using a corresponding number of GPU cold plates. Such GPU cold plates can be fluidically coupled with each other in series or in parallel, as described and shown above. Further, a hybrid cold plate based on this disclosure can be configured to cool any number of CPUs using a corresponding number of CPU cold plates. Such CPU cold plates can be fluidically coupled with each other in series or in parallel, as described and shown above. Moreover, the CPU cold plates can be fluidically coupled with the GPU cold plates in series (or in parallel), as shown above. Still further, a heat-exchanging manifold can be fluidically coupled with one or more of the GPU cold plates (or one or more of the CPU cold plates), in any combination based on the number of GPUs and CPUs in a given system.

Further, any number of plurality of hybrid cold plates as described herein can be fluidically coupled with each other in series or in parallel. As but one example, the cool coolant inlet shown in FIG. 2 can be fluidically coupled with a distribution manifold (not shown) configured to distribute coolant between or among a plurality of hybrid cold plates as shown in FIGS. 2 to 4. Similarly, the warm coolant outlet shown in FIG. 2 can be fluidically coupled with a collection manifold (not shown) configured to collect warm coolant from between or among the plurality of hybrid cold plates. In such an arrangement, the plurality of hybrid cold plates would be coupled with each other in parallel. In an alternative arrangement, the cool coolant inlet to one hybrid cold plate can be coupled with a source of cool coolant (e.g., a distribution manifold as just described or an outlet from a pump). The warm coolant outlet can be coupled with another hybrid cold plate of the type shown and described in, for example, FIG. 2 (or any other embodiment described herein), coupling these two hybrid cold plates with each other in series. Other embodiments fluidically couple one or more such hybrid cold plates in series with one or more other hybrid cold plates, some of which can be coupled with each other in parallel.

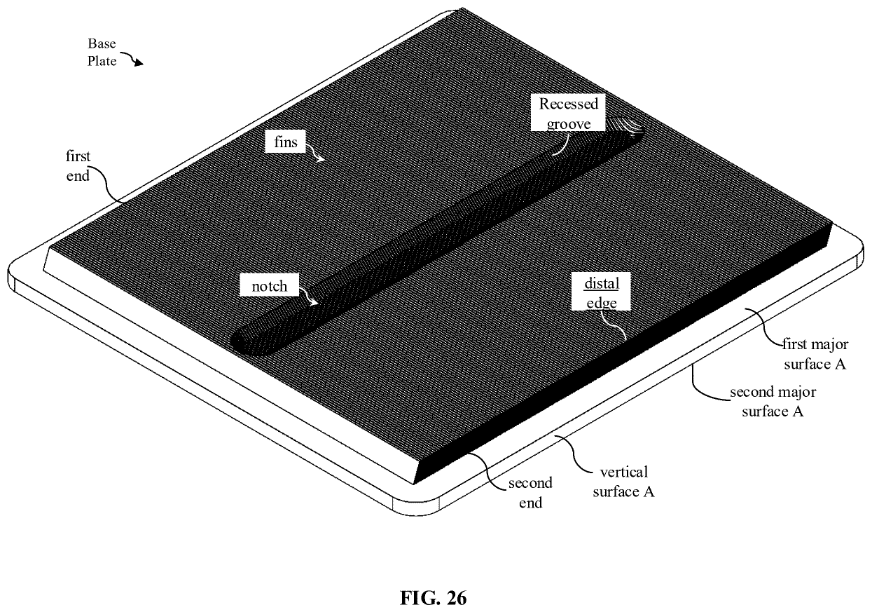

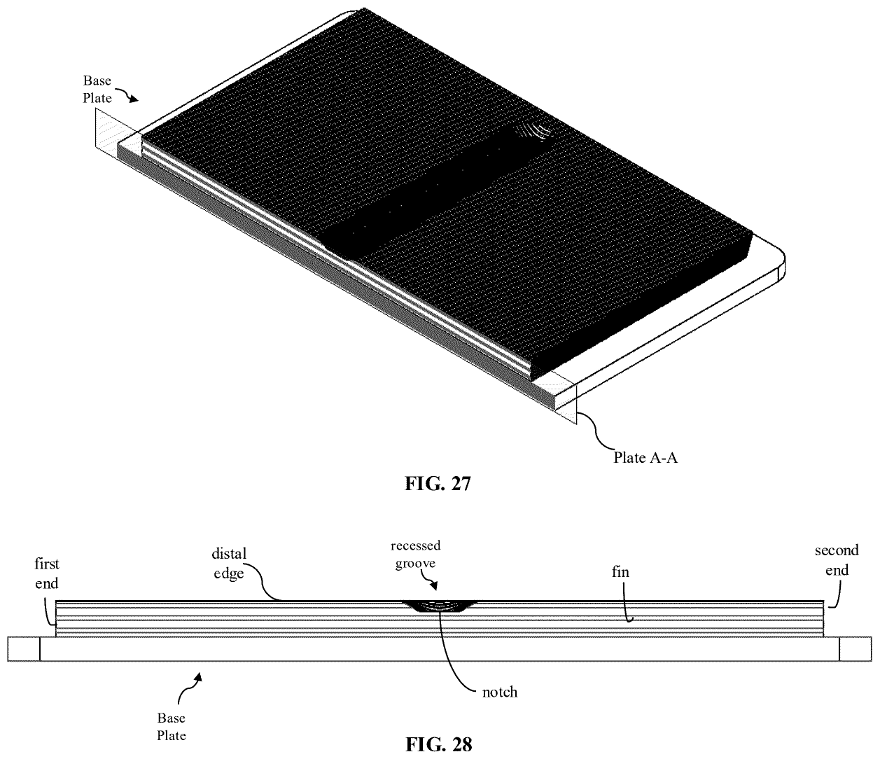

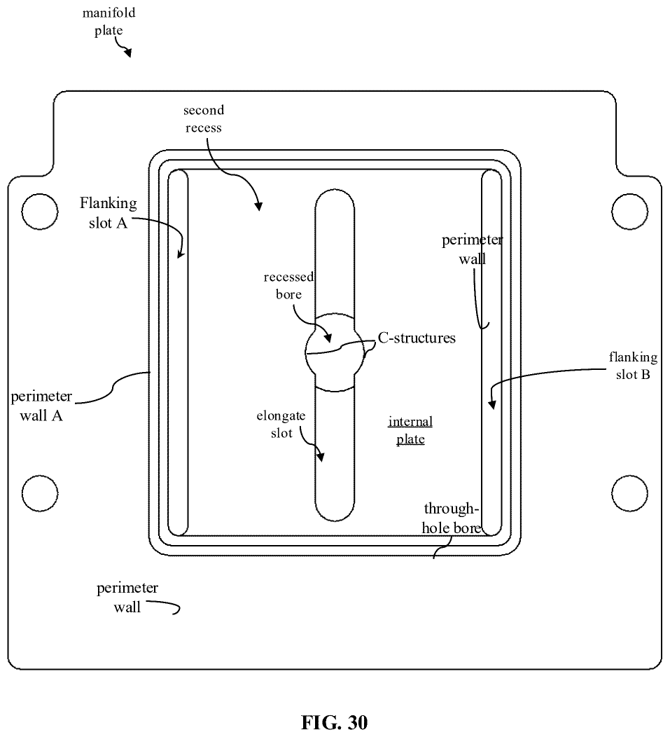

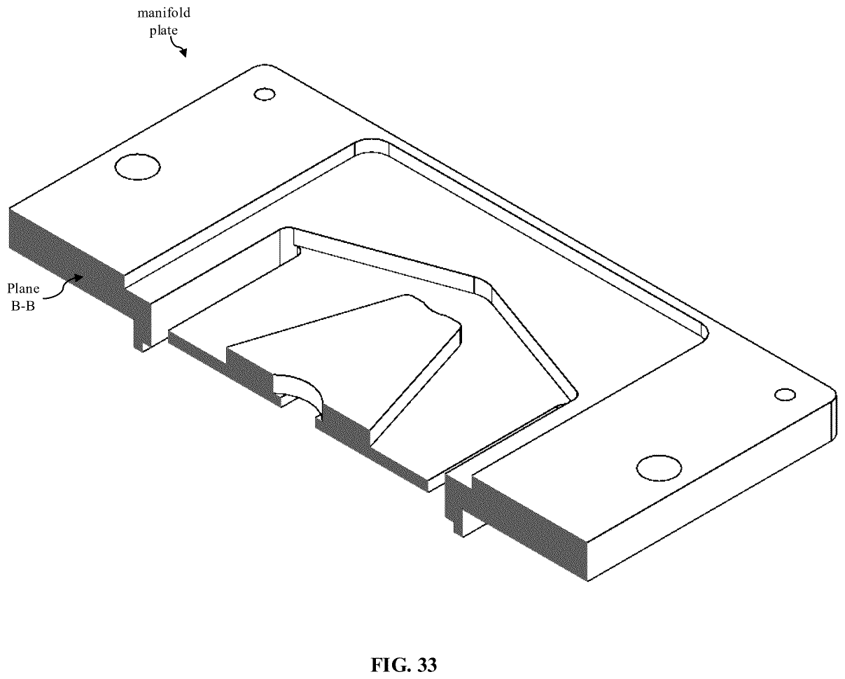

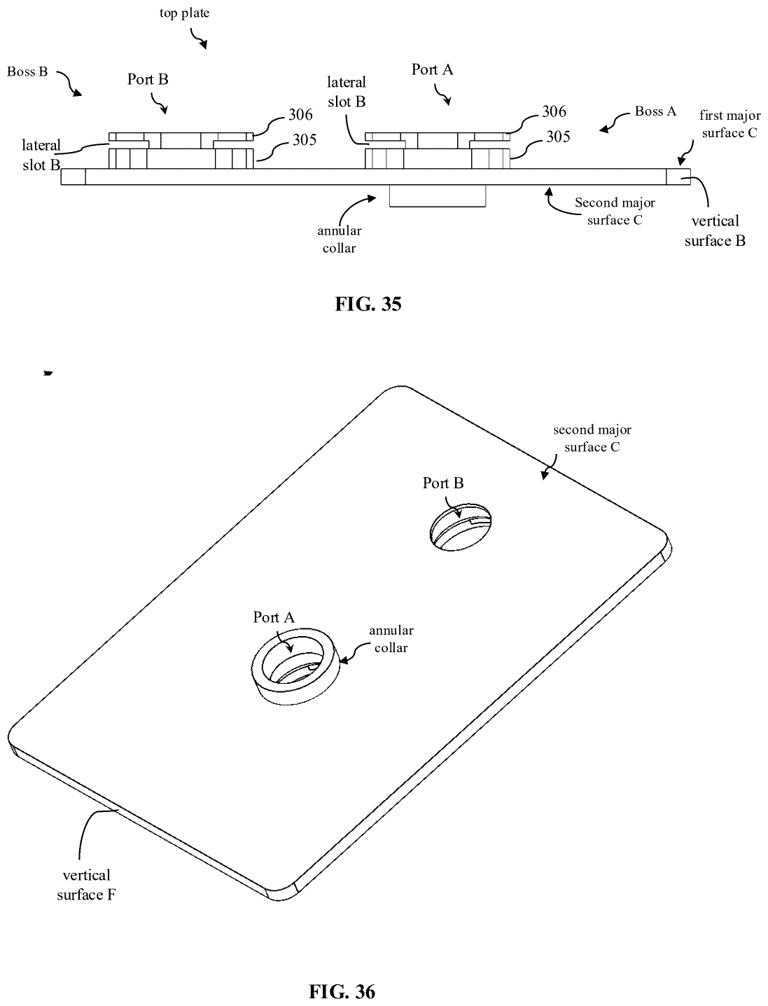

FIGS. 26-39 illustrate details of another embodiment of a cold plate suitable for use as a GPU or a CPU cold plate in connection with cooling devices and systems as described hereinabove. For sake of clarity, the following description of FIGS. 26-39 refers to a GPU or a GPU cold plate. Nevertheless, it shall be understood that cold plates (whether for use in single phase or two phase applications) for other heat-generating devices can embody one or more aspects of principles described in relation to a “GPU cold plate,” below. As shown in the exploded views in FIGS. 38 and 39, a GPU cold plate can include a manifold plate, a top plate, and a base plate.

FIGS. 26, 27, and 28 illustrate aspects of a base plate as may be incorporated in a GPU cold plate. Referring now to FIG. 26, which illustrates an isometric view of the base plate from above, the base plate comprises first major surface A and second major surface A. Second major surface A may be in thermal contact with a heat generating component such as, for example, a GPU. Heat generated by the heat generating component may be conductively transferred to second major surface A by way of the second major surface A being placed into thermal contact (with or without a thermal interface material) with the heat-generating component. A plurality of fins are disposed across the first major face A and extend therefrom. A microchannel is disposed between each fin, wherein the plurality of fins forms a plurality of microchannels, such that coolant can flow therethrough. The fins defining the plurality of microchannels can be in thermal contact with or extend continuously from the first major surface A, wherein heat conducted through the fins from second major surface A may be convectively transferred to coolant flowing through the plurality of microchannels. Each fin within the plurality of fins defines a first end, a second end, and a distal edge, as well as, optionally, a notch formed within the distal edge. When aligned, the internal notches of the plurality of fins define a recessed groove extending transversely across the tops of the fins and microchannels. In some embodiments, the recessed groove may extend across fewer than all of the fins, as shown in FIG. 26, and in other embodiments, the recessed groove may extend across all of the fins defined by the base plate. Coolant may flow from a region above (and including) the recessed groove into the plurality of microchannels or through the plurality of microchannels into a region above (and including) the recessed groove. In some embodiments, such as the embodiment shown in FIG. 26, the recessed groove may terminate at or near the outermost fins of the plurality of fins. Vertical surface A is disposed between first major surface A and second major surface A, wherein vertical surface A defines the perimeter of the base plate.

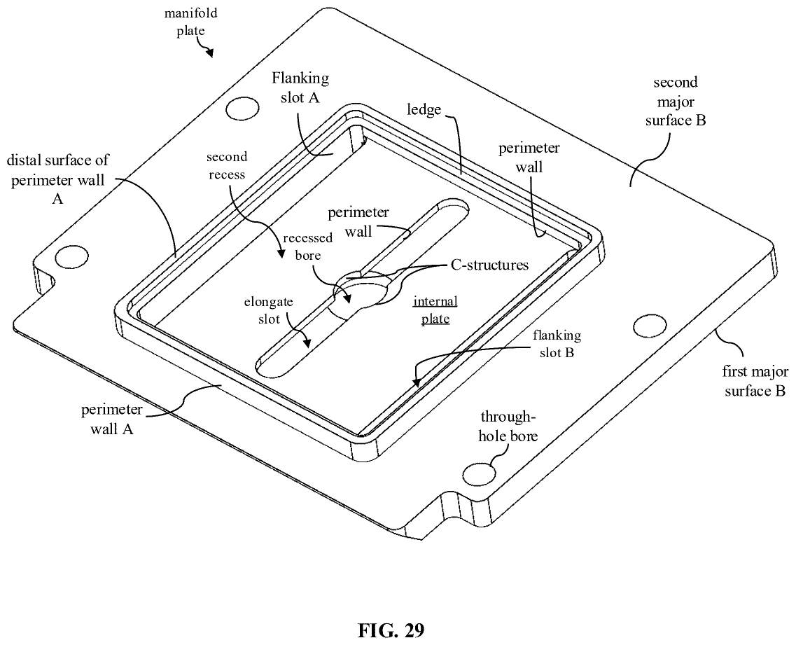

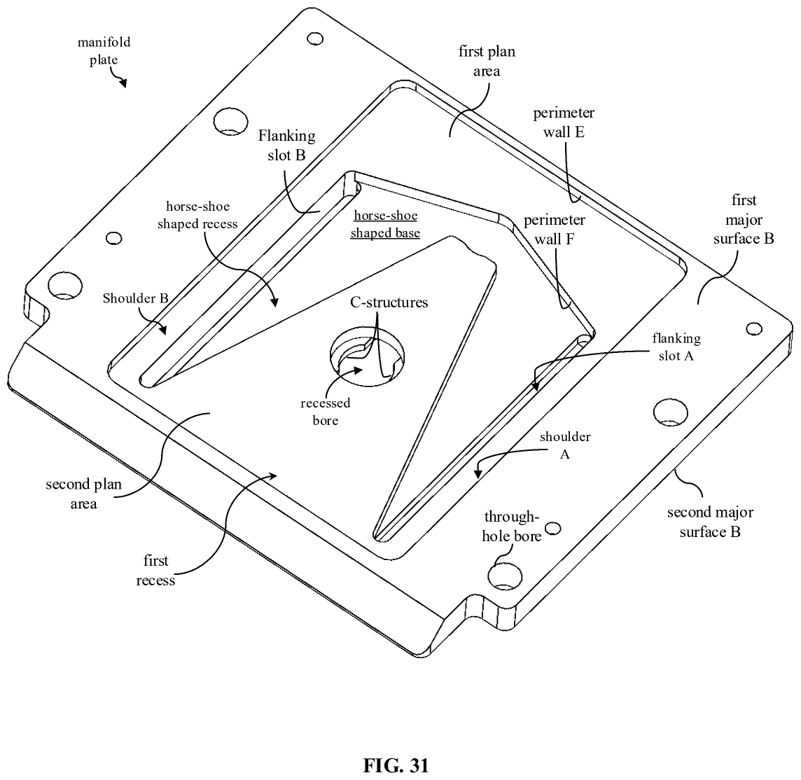

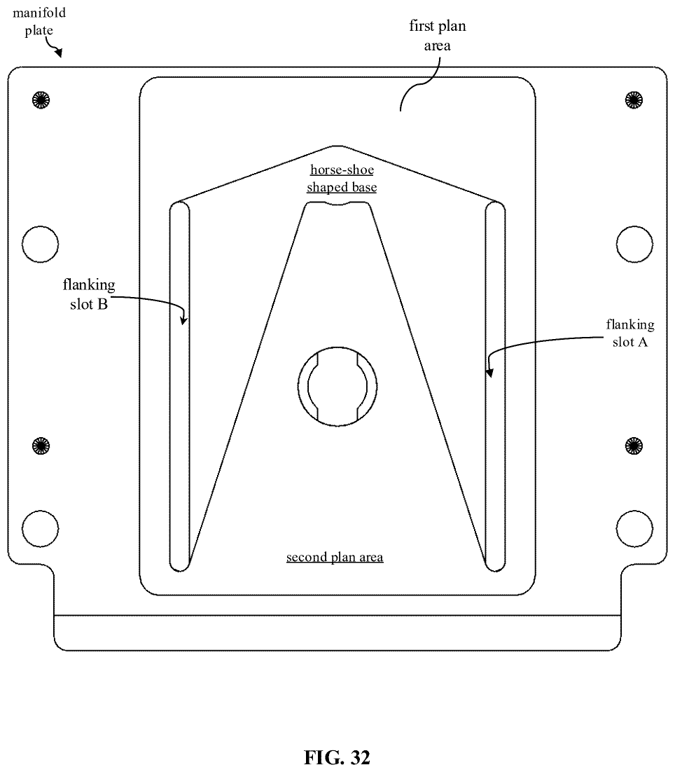

FIGS. 29, 30, 31, 32 and 33 illustrate aspects of an embodiment of a manifold plate suitable for being incorporated in a cold plate, e.g., a GPU cold plate. Referring now to FIG. 29, which illustrates a perspective view of the manifold plate from below, the manifold plate defines first major surface B and second major surface B, wherein second major surface B defines a second recess, and wherein perimeter wall A defines the boundary of the second recess. Perimeter wall A extends outwardly from, e.g., is raised relative to, the second major surface B, wherein perimeter wall A comprises a distal surface. A floor of the second recess may be above or below the second major surface B, or at a same elevation as the second major surface B relative to the distal surface defined by the perimeter wall A. A ledge is recessed from the distal surface of the perimeter wall within the second recess, defining an internal shoulder. The floor of the second recess is recessed below the shoulder relative to the disal surface of the perimeter wall A. An inwardly facing face (“wall B”) defines an outermost perimeter boundary of the second recess and extends around an outer perimeter surface (“vertical surface A”) of the base plate. As well, the floor of the second recess defines an internal plate, and an internally facing face (“wall C”) of the perimeter wall extends around the internal plate and defines an outer flow boundary of the open region around the microchannels and fins when the GPU cold plate is assembled. The dotted lines shown in FIG. 29 overlayed across the internal plate schematically illustrate indicate the region facing the distal edges of the fins, which may or may not contact the internal plate. The floor of the second recess (“internal plate”) defines a further, elongate recess, or slot. Perimeter wall D defines an outer perimeter boundary of the elongate slot, wherein perimeter wall D extends from the internal plate to a floor of the elongate slot, opposite of which (FIGS. 31, 32) are one or more of the “first plan area,” the “second plan area,” and the floor of the “horse-shoe shaped recess.” A through-hole bore (“recessed bore”) extends through the manifold plate from a floor of the second recess (shown in FIG. 29) to the “second plan area” (shown in FIG. 31). The elongate slot is in fluid communication with the recessed bore, wherein perimeter wall D forms internally facing regions of C structures corresponding to the recessed bore and the portion of the recessed bore recessed from the second plan area (FIG. 31) to the floor of the elongate slot (FIG. 29). Stated differently, an enlarged outer portion portion of the recessed bore extends from the base of the elongate slot to a second plan area (see FIG. 31). Flanking slots A and B are disposed through the manifold plate from the floor of the horse-shoe shaped recess (FIG. 31) to the floor of the second recess (FIG. 29), wherein flanking slots A and B define a first internal face extending through the manifold plate from the ledge (FIG. 29) of the second recess to the opposed shoulders A and B of a first recess (see FIG. 31) and a second internal face extending through the manifold plate from the floor of the second recess (FIG. 29) to a horseshoe shaped base (see FIG. 31). Through hole bores extend through first major surface B and the second major surface B. Through hole bores may receive fasteners or other mounting hardware for attaching the GPU cold plate to a motherboard, daughter card or other substrate or structure.

Referring now to FIG. 31, which illustrates a top-perspective view of the manifold plate, first major surface B defines a first recess, wherein perimeter wall E defines a perimeter boundary of the first recess. The floor of the first recess defines a further, horseshoe shaped region recessed from the floor of the first recess, wherein perimeter wall F defines an outer perimeter boundary of the horseshoe shaped recess. The horseshoe shaped recess extends to a floor (“horse shoe shaped base”) defined within horseshoe shaped recess. The horseshoe shaped recess may comprise a shape other than that of a horseshoe. For example, the recess may be a semi-circular, U-shaped or other recess shape recessed from the floor of the first recess, so as to define an open region through which coolant can flow between the flanking slots A, B. A first plan area and a second plan area are defined within the first major recess, wherein opposed shoulders A and B extend from the first plan area to the second plan area, and wherein the opposed shoulders A and B are disposed laterally outward of the horseshoe shaped base.

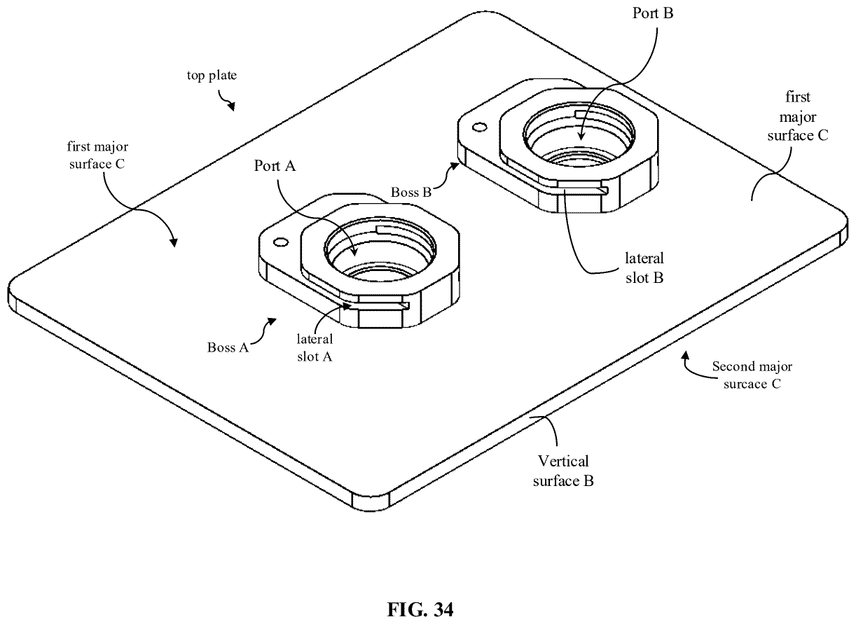

The recessed bore together with the elongate slot partially define a first manifold (that, with a base plate as in FIG. 26 that includes a transverse groove across the fins, can be in fluid communication with the recessed groove) this overlies the fins of the base plate and is in fluid communication with the microchannels between the fins, wherein the first manifold is in fluid communication with the recessed groove of the base plate and port A of the top plate (see FIG. 34). The first manifold is configured to collect coolant from the opposed ends of the plurality of microchannels or distribute coolant among the microchannels. As well, port A (see FIG. 34) is in fluid communication with the manifold, allowing, for example, the manifold to receive coolant from port A or to convey coolant to port A, depending on whether the GPU cold plate operates in a split-flow mode (coolant flows from the manifold into the microchannels, where it bifurcates and flows outward to the microchannel ends) or in a convergent flow mode (coolant enters the opposed ends of the microchannel and flows inwardly toward a middle region of the microchannels, where the inwardly directed flows of coolant converge, mix and exit to the manifold).

The horseshoe shaped recess together with flanking slots A and B partially define a second manifold in fluid communication with the opposed ends of the microchannels defined the base plate and port B of the top plate (see FIG. 34). The second manifold is configured to collect coolant from the opposed ends of the microchannels (in a split flow mode) or distribute coolant among the opposed ends of the plurality of microchannels (in a convergent flow mode). Port B (see FIG. 34) is in fluid communication with the second manifold.

As discussed with reference to FIG. 29a, the distal edge of the plurality of fins can be positioned adjacent or adjoining the internal plate of the manifold plate. When the distal edge of the plurality of fins and the internal plate are in contact (or in close proximity, leaving a small gap therebetween), coolant flowing through the plurality of microchannels is inhibited or prevented from leaking out of the microchannels past the distal edge of the fins, ensuring that coolant flows through the microchannels from the first manifold to the second manifold, or from the second manifold to the first manifold, without bypassing the plurality of microchannels.

FIGS. 34, 35, 36 and 37 illustrate an embodiment of a top plate for a GPU (or other) cold plate. Referring now to FIG. 34, which illustrates a top-perspective view of the top plate, the top plate defines a first major surface C and a second major surface C, wherein vertical surface B is defined between first major surface C and second major surface C. First major surface C comprises boss A, wherein boss A is configured to receive a turret as described hereinbefore. For example, boss A may comprise lateral slot A wherein lateral slot A is configured to receive a clip that secures a turret to boss A. Port A is defined within boss A, wherein port A extends through first major surface C and second major surface C, such that port A (or an internal passage through the turret) is in fluid communication with the recessed bore of the manifold plate (see FIG. 31) when the exemplary GPC cold plate is assembled (see, e.g., FIGS. 38 and 39 and the corresponding description). Accordingly, port A can be in fluid communication with the first manifold, wherein coolant may flow through port A into the first manifold or through the first manifold into Port A. First major surface C further defines boss B, wherein boss B is configured to receive a turret as described hereinbefore. For example, boss B may comprise lateral slot B wherein lateral slot B is configured to receive a clip that secures a turret to boss B. Port B is defined within boss B, wherein port B extends through first major surface C and second major surface C, such that port B (or an internal passage through the turret) is in fluid communication with the horseshoe shaped recess of the manifold plate (see FIG. 31) when the exemplary GPC cold plate is assembled (see FIGS. 38 and 39 and the corresponding description). Accordingly, port B is in fluid communication with the second manifold, wherein coolant may flow through port B into the second manifold or through the second manifold into Port B. Furthermore, ports A and B may be coupled to a conduit to receive and/or dispel coolant therethrough.

Referring now to FIG. 36, which illustrates a bottom-perspective view of the top plate, second major surface C defines, in this embodiment, an annular collar disposed circumferentially around port A, thereby extending port A to a distal face (relative to the second major surface C defined by the top plate) of the annular collar. The illustrated annular collar is configured to mate with the recessed bore of the manifold plate (see FIG. 31), and the distal surface of the annular collar is configured to mate with the C structures of the manifold plate (see FIG. 31). In some embodiments, the annular collar comprises a shape that is not annular. For example, some embodiments of the top plate may comprise a collar comprising a shape that is square, ovular, or triangular, or any other arbitrary shape (similarly, each bore described herein need not be circular and can in some embodiments by any selected shape). Accordingly, the C structures and recessed bore of the manifold plate may define a contour corresponding to a complementary contour defined by the collar of the top plate. In some embodiments, the manifold plate may comprise a collar surrounding recessed bore that is configured to mate with Port A or a complementary recess in fluid communication therewith. In such embodiments, port A can define a recessed ledge configured to mate with the distal surface of the annular collar.

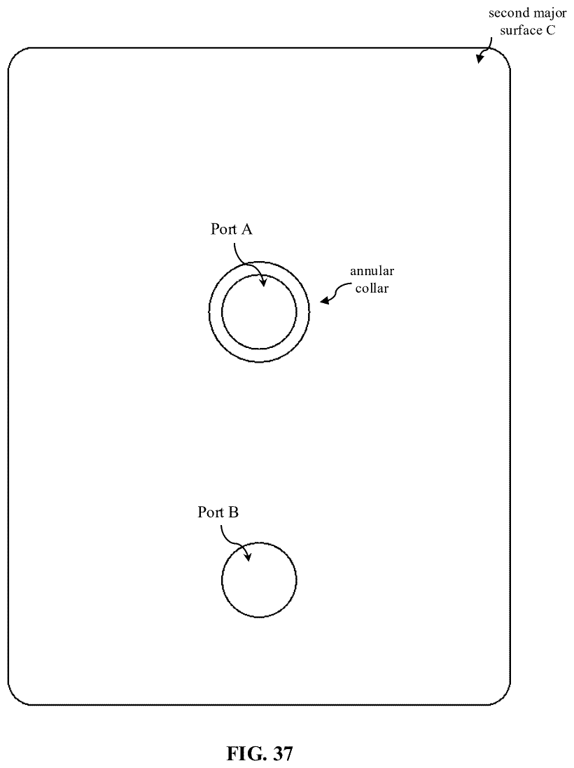

FIGS. 38 and 39 illustrate exploded views of the illustrative GPU cold plate. When the illustrated GPU cold plate is assembled, the top plate mates with the manifold plate within the first recess of the manifold plate shown in FIG. 31. In such a mating relationship, the second major surface C is in opposed relation to the horizontal surfaces of the first recess, for example the first plan area, the second plan area, and the shoulders A and B to facilitate bonding, adhesion, fusing (e.g., brazing, soldering, friction or other stir welding) of the top plate to the manifold plate. FIG. 37 illustrates an overlay of theses areas on second major surface C, wherein the overlaid areas indicate areas to which second major surface C is in opposed relation. Furthermore, vertical surface B is in opposed relation to perimeter wall E and the annular collar is in opposed relation to the recessed bore, wherein the distal edge of the annular collar is in opposed relation to the C structures (as discussed with reference to FIG. 34).

Additionally, when the exemplary GPU cold plate is assembled, the base plate mates with the manifold plate within the second recess of the manifold plate as shown in FIG. 29. Specifically, first major surface A is in opposed relation to the ledge of the second recess. Vertical surface A is in opposed relation to perimeter wall B. The distal edge of the plurality of fins is in opposed relation to the internal plate of the manifold plate (as discussed with reference to FIG. 29).

The structures that are in opposed relation to one another can be joined to define a sealing (e.g., a state of being sealed) interface. A sealing interface may be formed between structures in opposed relation through bonding, adhesion and/or fusing. For example, structures in opposed relation may optionally have a gasket or a seal positioned between opposed surfaces of the opposing structures, and the opposing structures may be fastened together using screws, clamps, rivets, pins, and/or other fasteners. Such gaskets and seals can enhance the ability of opposed faces to form a sealing interface between the joined structures. In still other embodiments, the structures in opposed relation may comprise complementary features that allow the structures in opposed relation to matingly engage with each other to form a sealing interface (with or without an intermediate gasket). When fully assembled as described with reference to FIGS. 38 and 39, the exemplary GPU cold plate forms a network of sealing interfaces that allow coolant to flow through the first manifold, the second manifold, and the plurality of microchannels without leakage.

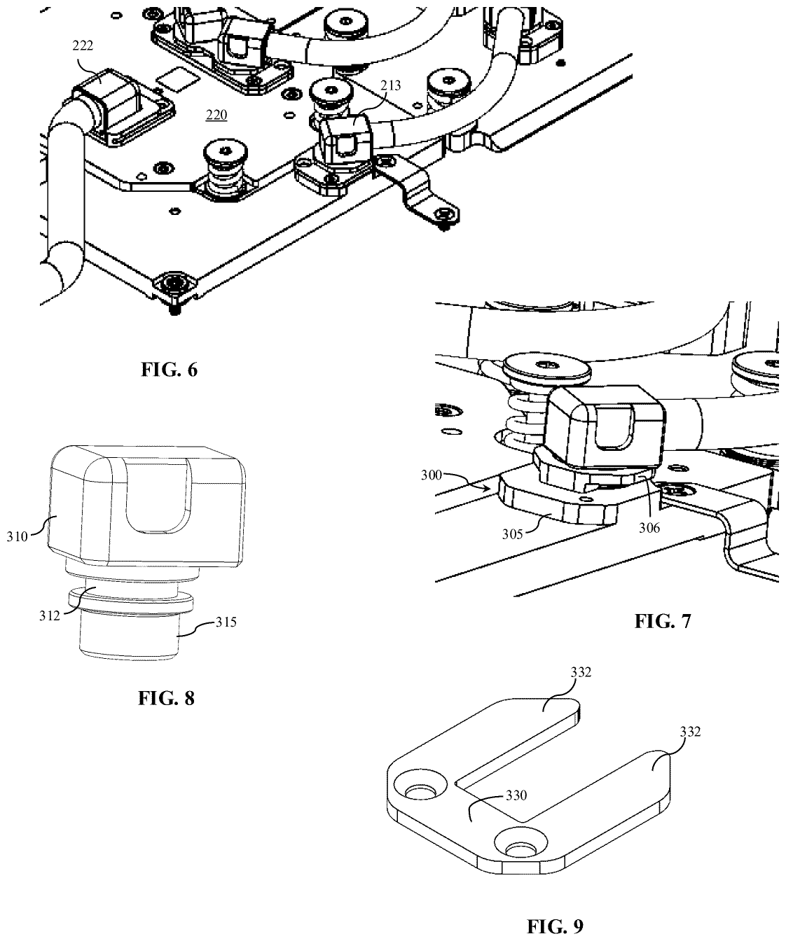

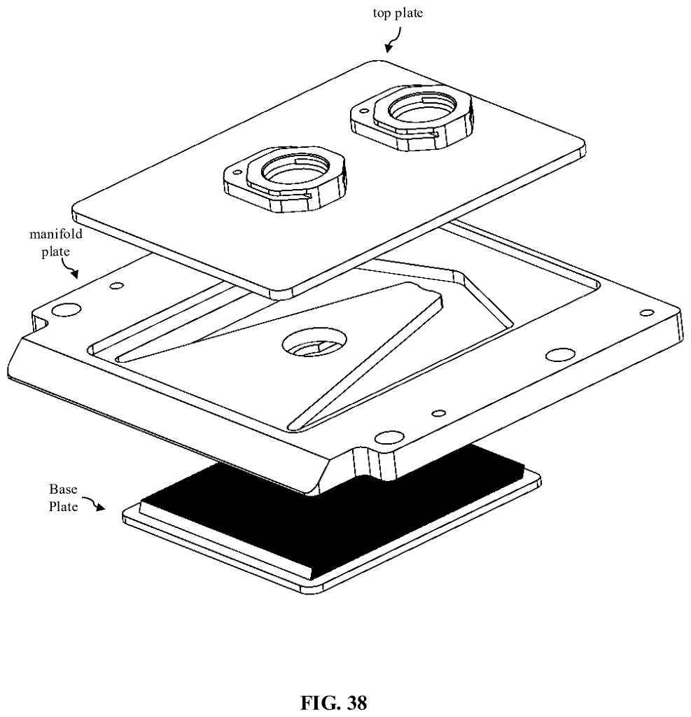

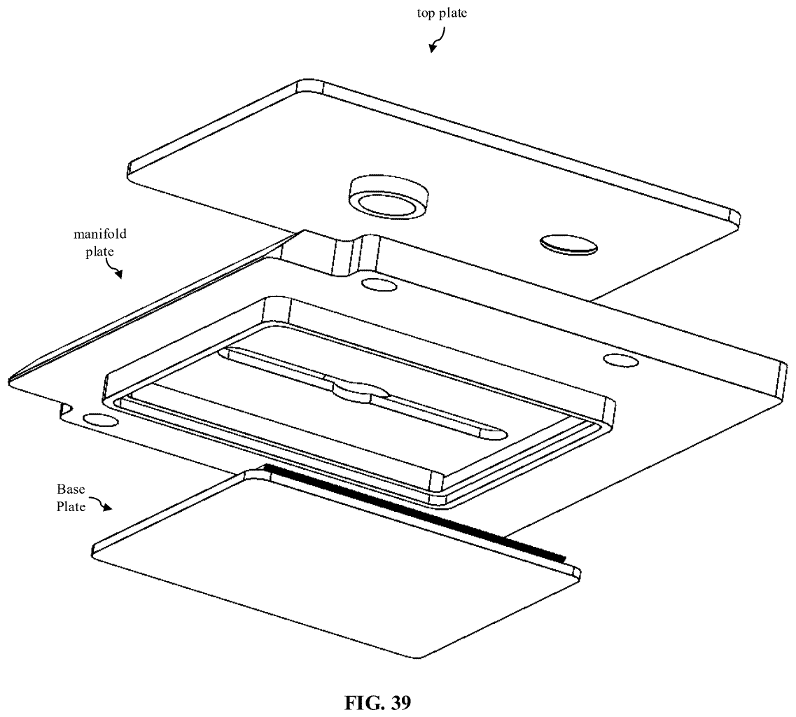

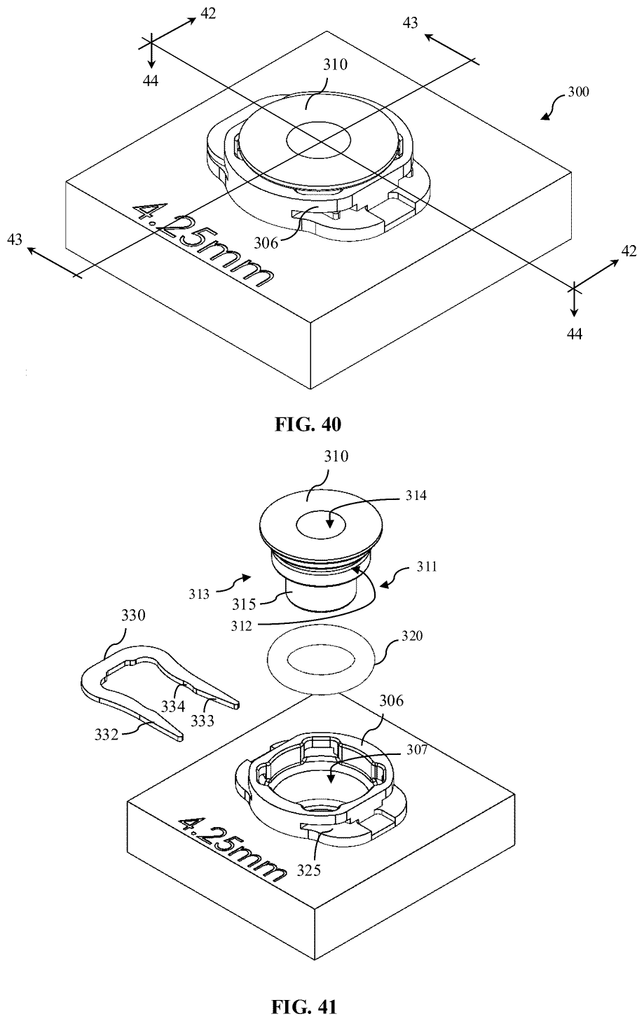

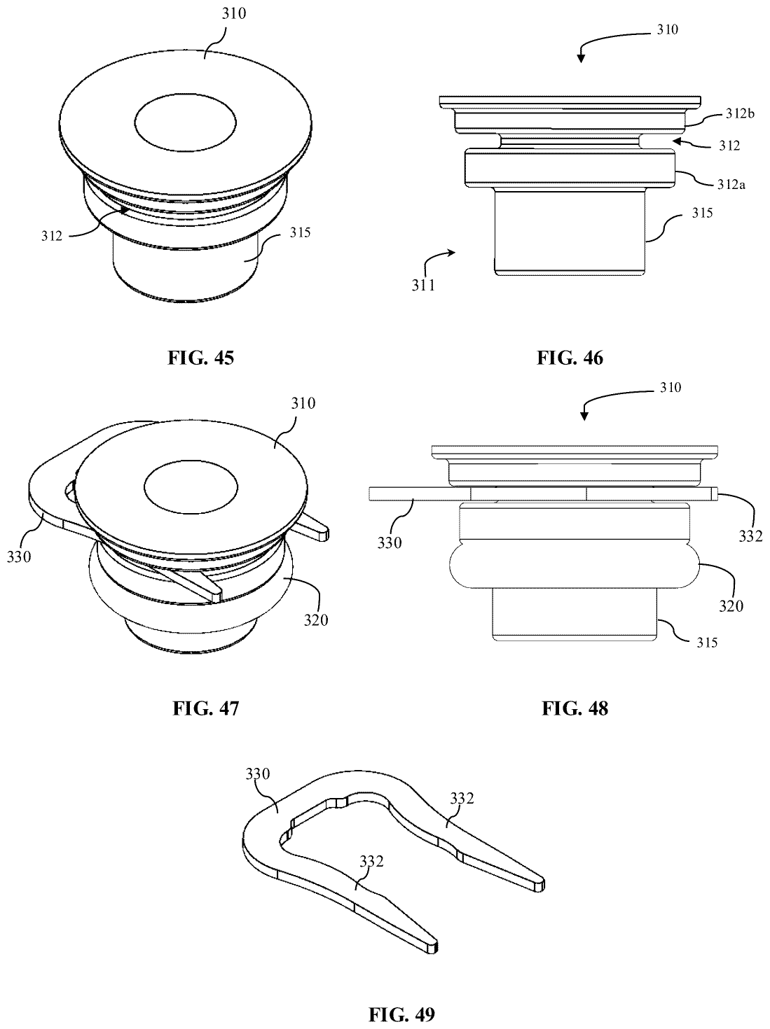

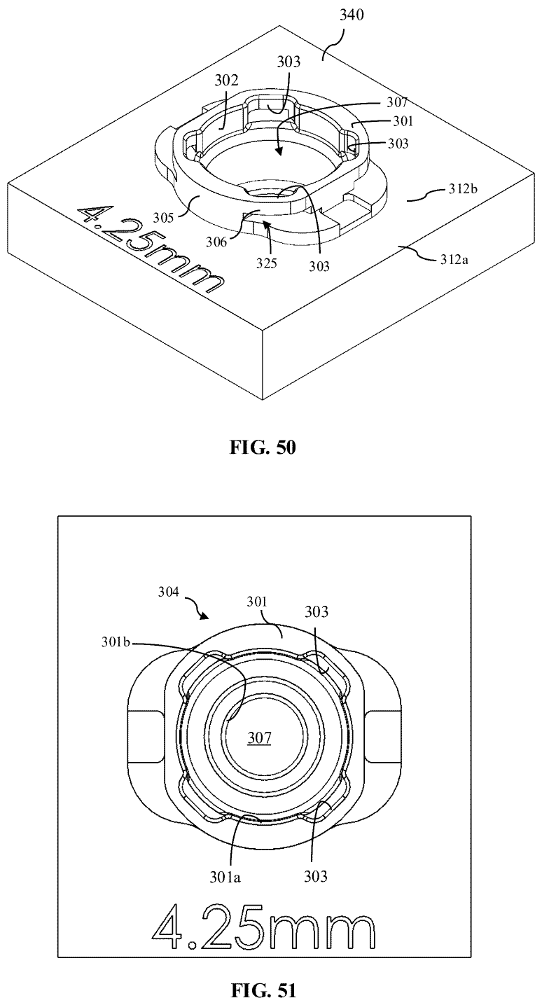

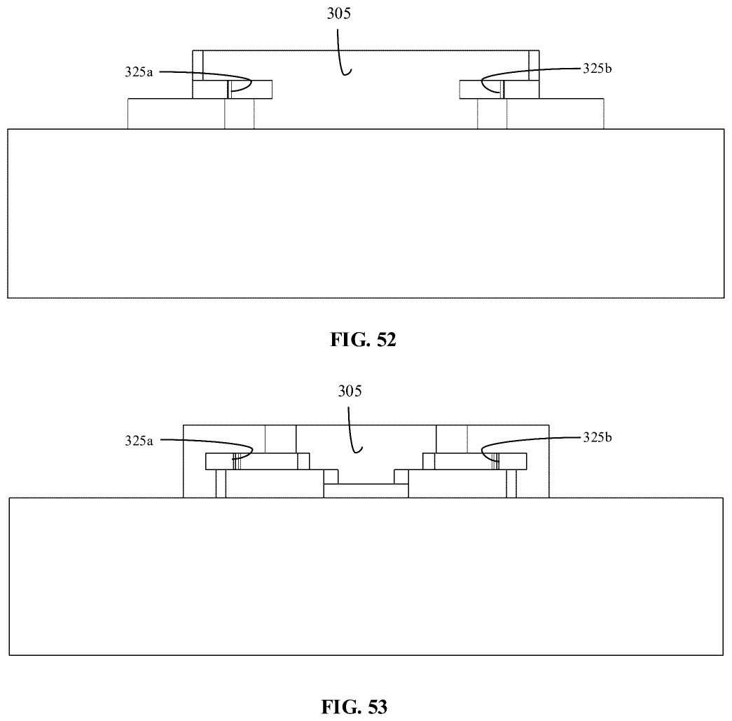

Referring now to FIGS. 40-53, a representative fluid connection as shown in FIGS. 6, 7, 8 and 9 will be described. Generally speaking, a fluid connection 300 as in FIGS. 6 and 40 has a raised boss 305 that defines a raised flange 306 and an internal bore 307. A fluid connector 310 (e.g., a “turret” as in FIG. 8) has a distal portion 311 that seats within the internal bore 307 and an annular gap 312 or recess positioned proximally of the distal portion. An O-ring 320 (FIG. 41) can prevent or inhibit leakage of coolant between an external surface 313 of the fluid connector and the internal bore 307 through the housing wall. A retainer clip 330 can be positioned beneath the raised flange 306 and within the annular gap 312 or recess to capture the distal portion of the fluid connector within the raised boss.

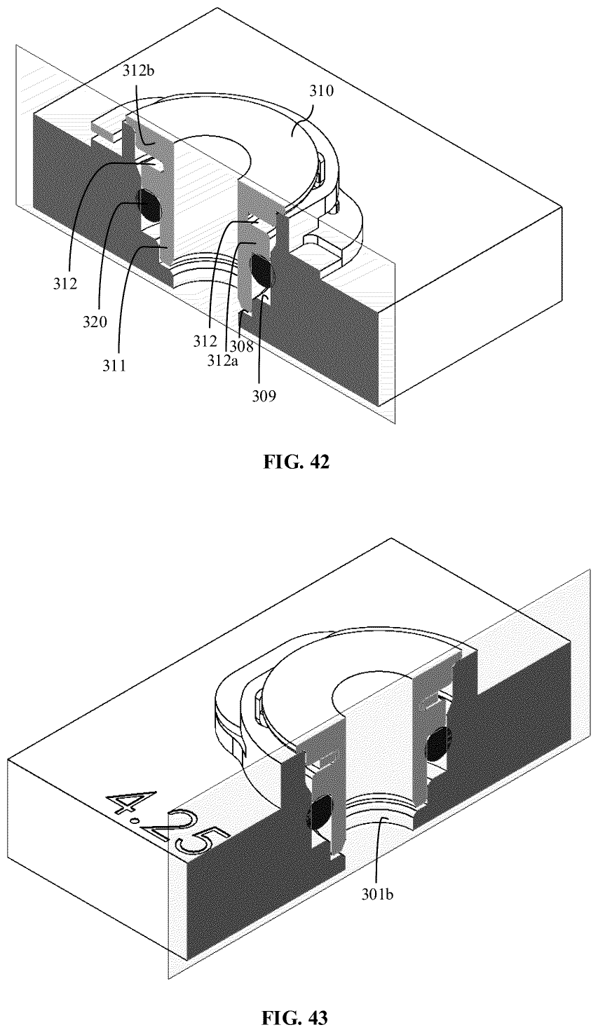

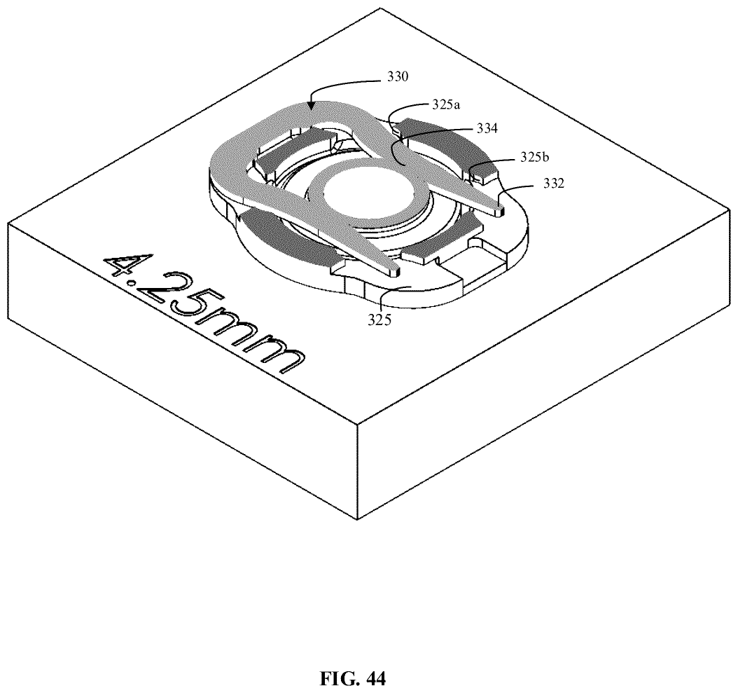

FIG. 41 shows an exploded view of such a fluid connection 300, with the fluid connector 310 extracted in the +Z-direction and the retainer clip extracted along the −X-direction (according to the coordinate system depicted in FIG. 40). The cross-sectional view in FIG. 42 shows a fluid passageway 314 extending through the fluid connector 310 The piston 315 of the fluid connector 310 is shown positioned within the internal bore 307 of the raised boss 305, with a distal end of the piston 315 positioned adjacent a second shoulder 308 recessed from a first shoulder 309. Between the annular ring 312a defined by the fluid connector and the first shoulder 309 defined by the internal bore, an O-ring 320 gland is positioned to providing sealing engagement between the fluid connector and the inner surface of the internal bore. As also shown in the section view of FIG. 42, as well as in FIG. 46, the annular ring 312a is longitudinally spaced apart (in a distal, or −Z-direction) from an annular portion 312b of the fluid connector, defining an annular gap 312, or recess. As the section views in FIGS. 43 and 44, and the elevation views in FIGS. 48 and 40 show, the opposed arms 332 of the retainer clip 330 (FIGS. 44 and 49) can extend within the annular gap, or recess 312, and extend through opposed undercut regions 325 of the raised boss 305 to capture the fluid connector 310 within the internal bore 307.

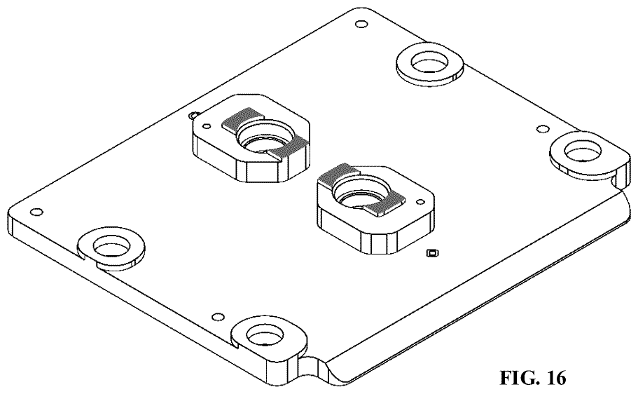

As FIGS. 7, 10, 14 to 16, 41, 51 to 53 show, a raised boss can define an internal bore, an outer peripheral surface, and an undercut slot extending from the outer peripheral surface to the internal bore. In some embodiments, as shown, the raised boss define a second undercut slot defining an opening extending from the outer peripheral surface to the internal bore. As the section views in FIGS. 16 and 44 show, a portion of the peripheral wall of the raised boss extends from the first undercut slot to the second undercut slot, providing a solid boundary of the internal bore positioned between the first undercut slot to the second undercut slot. As a comparison of FIGS. 15 and 16, and a comparison, for example, of FIGS. 40 and 44, show the undercut slot can be positioned distally of the upper surface of the raised boss to define a raised flange, under which the retainer clip can extend through a recessed portion of the fluid connector so as to retain the fluid connector with regard to the raised boss (and thus the housing of the cold plate).

A raised boss and raised flange as shown among the various drawings offers several advantages over prior fluid connections for cold plates. For example, a billet of copper or aluminum (or other material from which a cold plate housing may be produced, e.g., a thermoformed plastic, an injection-molded plastic, etc.) can be milled to reveal a raised portion of the boss. The internal bore can be machined, e.g., with a single milling tool that has one or more shoulders configured to mill the shoulders defined by the internal bore. A keyhole cutter can be used to undercut one or more regions of the raised boss to reveal the raised flange. Moreover, the undercut region can extend through an external peripheral wall _ defined by the raised flange _ to provide an opening (e.g., an open slot) through which a portion (e.g., an edge) of the retainer clip can extend into the internal bore. The portion of the retainer clip that extends into the internal bore can also pass through the annular recess (or gap) defined by the fluid connector to capture the fluid connector within the machined internal bore. Moreover, the configuration of the raised boss, undercut region (which defines the raised flange), and internal bore can be machined using as few as two tools (e.g., a tool for revealing the raised boss and forming the internal bore, and a keyhole cutter for providing the undercut slot/raised flange) on a single-axis milling machine. Such an arrangement can thus be produced quickly and efficiently. Still further, such an arrangement can substantially reduce the depth of material required for fluid connections, making disclosed fluid connections much lower profile than prior fluid connections. For example, prior fluid connectors used pins that measured 1.6 mm in diameter (requiring material extending around a 1.6 mm bore). By contrast, disclosed fluid connections can incorporate a 0.5 mm thick retainer clip (sufficient to retain in excess of a 300 N axial load), allowing the overall height of the raised boss to be less than the diameter of prior-art pins.

As FIGS. 44 and 50 to 53 show, a proximal portion of the internal bore 307, e.g., positioned adjacent the aperture in the upper surface 301 of the raised boss 305, can define a fluted periphery 302 (e.g., a periphery having a fluted region 303). Each fluted region 303 is defined by a radial enlargement of internal bore 307. The radial enlargement extends circumferentially, defining an arcuate segment. The plurality of fluted regions 303 are circumferentially spaced around the internal bore. The illustrated embodiment has four fluted regions 303. Each fluted region 303 provides a convenient region to undercut, as the peripheral wall 304 is thinner in the fluted regions, thus requiring a thinner undercut to provide the through-wall openings (or slots) extending from the outer surface of the peripheral wall 304 to the fluted region 303 through which the arms 332 of the retainer clip 330 can pass. The thinner wall can thus speed the process of undercutting.

As the drawings show, a fluid connector 310 can have a distal portion 311 positioned within the internal bore 307 and a proximal portion extending from the raised boss. The proximal portion can include a fitting for coupling with a conduit and an internal passage through the fluid connector can fluidly couple an interior passage of a cold plate with the conduit, enabling a plurality of fluid components and/or cold plates to be coupled together within fluid networks as depicted in FIGS. 22 to 35, for example. As, for example, FIGS. 43 and 44 show, an external surface of the fluid connector can have an annular recess 312 aligned with the undercut slot 325, an annular ring 312a positioned distally of the annular recess 312 and an O-ring 320 can be positioned around the fluid connector at a position distal of the annular ring 312a.

A retainer clip 330 can have an arm 332 extending through the undercut slot 325 and within the annular recess 312 of the fluid connector 310 to capture the distal portion 311 of the fluid connector within the internal bore.

As FIG. 44 shows, a plurality of undercut slots 325 can be spaced apart from each other circumferentially. The retainer clip 330 can be U-shaped and have a pair of spaced-apart arms 332. In FIG. 44, the spaced-apart arms 332 are so sized to extend from external to the peripheral wall 301 through the first undercut slot 325a and the second undercut slot 325b. In other embodiments, at least one of the spaced-apart arms is so sized to extend from external to the peripheral wall through the first undercut slot and the second undercut slot. An inner edge of the arm 332 is positioned adjacent the external surface of the fluid connector 310. As FIG. 49 shows, the inner edge 333 has detente region 334 so configured to urge against the external surface of the fluid connector 310 as to inhibit the U-shaped clip from backing out of the first undercut slot 325a and the second undercut slot 325b.

Fluid connections shown and described in relation to undercut slots and raised flanges (e.g., in FIGS. 6 to 9 and 40 to 53) can be incorporated in cold plates and hybrid cold plates as disclosed herein to provide convenient, low cost and low profile fluid couplings suitable for fluid networks, including, for example, as shown among FIGS. 22 to 25. Fluid connectors as shown and described in connection with FIGS. 8, 45, and 46 can be configured and produced according to the teachings in U.S. patent application Ser. No. 17/689,879, filed Mar. 8, 2022, the contents of which are hereby incorporated as completely as if reproduced herein in full, for all purposes.

For example, a cold plate having an inlet, an outlet, and a passageway configured to convey a fluid from the inlet to the outlet can include a housing wall having an internal surface defining a boundary of the passageway and an external surface. As shown among FIGS. 40 to 56, a raised boss 305 can extend from the external surface of the housing wall 340 to an upper surface 301. The upper surface of the raised boss can define an aperture 301a. As shown, the raised boss and housing wall define a through-hole recess 307 extending from the aperture 301a in the upper surface 301 of the raised boss 305 to an opposed opening 301b through the boundary of the passageway defined by the housing wall 340. The raised boss defines a peripheral wall 304 extending around the through-hole recess. The peripheral wall has an inner surface corresponding to the through-hole recess and outer peripheral surface wherein the raised boss defines an undercut slot 325 positioned between the external surface of the housing wall and the upper surface of the raised boss. The undercut slot 325 defines an opening extending from the outer peripheral surface to the through-hole recess 307.

As the section view in FIG. 42 shows, the through-hole recess defines a first shoulder 309 positioned distally of the fluted periphery 302. The through-hole recess defines a second shoulder 308 positioned distally of the first shoulder and proximally of the opening 301b through the boundary of the passageway defined by the housing wall.

A spring clip 330 has a leg 332 configured to extend through the undercut slot 325 transversely relative an axis parallel to the longitudinal axis. A fluid connector has an external surface so complementarily shaped relative to the through-hole recess as to be matingly receivable by the through-hole recess.

The fluid connector also defines a distal piston 315 and an annular ring 312a extending circumferentially around the piston proximally positioned of the distal piston. In FIG. 42, the annular ring 312a is a first annular ring and the fluid connector also defines a second annular ring 312b positioned proximally of and spaced apart from the first annular ring, defining an annular gap 312 positioned therebetween.

An O-ring 320 (FIG. 47) extends around the piston 315 at a position distally of the first annular ring 312a. The annular gap 312 aligns with the opening defined by the undercut slot 325 when the fluid connector 310 and O-ring 320 are seated within the through-hole recess. The leg 322 of the spring clip 330 extends through the opening defined by the undercut slot and through the annular gap defined by the fluid connector, retaining the fluid connector within the recessed through-hold aperture.

As FIG. 49 shows, the spring clip can be a U-shaped spring clip configured to capture the fluid connector within the raised boss defined by the cold plate housing.

Some embodiments described herein can be used to cool one or more multi-chip modules, each having a plurality of active electronic components that generate heat while operating. Nonetheless, this disclosure is provided to enable a person skilled in the art to make or use embodiments of the disclosed principles. Embodiments other than those described herein or shown among the drawings are contemplated based on the principles disclosed herein, together with any attendant changes in configurations of the respective apparatus or changes in order of method acts described herein, without departing from the spirit or scope of this disclosure. Various modifications to the examples described herein will be readily apparent to those skilled in the art.

For example, concepts described herein can be used to cool a plurality of other types of heat-generating components that are combined into a functional module (e.g., as with a DIMM or another multichip module, e.g., a processing unit that includes one or more processing cores or chips, together with one or more voltage regulating components (so-called “VR components”) or other modules that include, for example, a so-called intermediate bus converter (IBC). For example, an assembly of cold plates as shown among FIGS. 2 to 21 can span across a plurality of such alternative components, even when the components have different heights from each other relative to the substrate to which they are mounted (e.g., by using concepts described herein, such as, for example, deforming a passive heat-transfer component or a compressible thermal interface material).

Directions and other relative references (e.g., up, down, top, bottom, left, right, rearward, forward, etc.) may be used to facilitate discussion of the drawings and principles herein, but are not intended to be limiting. For example, certain terms may be used such as “up,” “down,”, “upper,” “lower,” “horizontal,” “vertical,” “left,” “right,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper” surface can become a “lower” surface simply by turning the object over. Nevertheless, it is still the same surface, and the object remains the same. As used herein, “and/or” means “and” or “or”, as well as “and” and “or.” Moreover, all patent and non-patent literature cited herein is hereby incorporated by reference in its entirety for all purposes.

And, those of ordinary skill in the art will appreciate that the exemplary embodiments disclosed herein can be adapted to various configurations and/or uses without departing from the disclosed principles. Applying the principles disclosed herein, it is possible to provide a wide variety of cooling devices for multi-chip modules, and related methods and systems to remove waste heat from such multi-chip modules. For example, the principles described above in connection with any particular example can be combined with the principles described in connection with another example described herein. Thus, all structural and functional equivalents to the features and method acts of the various embodiments described throughout the disclosure that are known or later come to be known to those of ordinary skill in the art are intended to be encompassed by the principles described and the features and acts claimed herein. Accordingly, neither the claims nor this detailed description shall be construed in a limiting sense, and following a review of this disclosure, those of ordinary skill in the art will appreciate the wide variety of cooling devices, and related methods and systems that can be devised using the various concepts described herein.

Moreover, nothing disclosed herein is intended to be dedicated to the public regardless of whether such disclosure is explicitly recited in the claims. No claim feature is to be construed under the provisions of 35 USC 112(f), unless the feature is expressly recited using the phrase “means for” or “step for”.

The appended claims are not intended to be limited to the embodiments shown herein, but are to be accorded the full scope consistent with the language of the claims, wherein reference to a feature in the singular, such as by use of the article “a” or “an” is not intended to mean “one and only one” unless specifically so stated, but rather “one or more”. Further, in view of the many possible embodiments to which the disclosed principles can be applied, we reserve the right to claim any and all combinations of features and technologies described herein as understood by a person of ordinary skill in the art, including the right to claim, for example, all that comes within the scope and spirit of the foregoing description, as well as the combinations recited, literally and equivalently, in any claims presented anytime throughout prosecution of this application or any application claiming benefit of or priority from this application, and more particularly but not exclusively in the claims appended hereto.

We currently claim:

1. A cold plate having an inlet, an outlet, and a passageway configured to convey a fluid from the inlet to the outlet, the cold plate comprising:
a housing wall having an internal surface defining a boundary of the passageway and an external surface;
a raised boss extending from the external surface of the housing wall to an upper surface, wherein the upper surface of the raised boss defines an aperture, wherein the raised boss and housing wall define a through-hole recess extending from the aperture in the upper surface of the raised boss to an opposed opening through the boundary of the passageway defined by the housing wall, wherein the raised boss defines a peripheral wall extending around the through-hole recess, the peripheral wall having an inner surface corresponding to the through-hole recess and outer peripheral surface, wherein the raised boss defines an undercut slot positioned between the external surface of the housing wall and the upper surface of the raised boss, wherein the undercut slot defines an opening extending from the outer peripheral surface to the through-hole recess.

2. The cold plate according to claim 1, wherein the undercut slot is a first undercut slot, wherein the raised boss defines a second undercut slot defining an opening extending from the outer peripheral surface to the through-hole recess.

3. The cold plate according to claim 2, wherein a portion of the peripheral wall of the raised boss extends from the first undercut slot to the second undercut slot, providing a solid boundary of the through-hole recess positioned between the first undercut slot to the second undercut slot.

4. The cold plate according to claim 1, wherein the undercut slot is positioned distally of the upper surface of the raised boss.

5. The cold plate according to claim 1, wherein the through-hole recess defines a proximal portion positioned adjacent the aperture in the upper surface of the raised boss to a distal portion positioned adjacent the opening through the boundary of the passageway, wherein the proximal portion of the through-hole recess defines a fluted periphery having a fluted region.

6. The cold plate according to claim 5, wherein the fluted regions is defined by a radial enlargement of the through-hole recess extending through an arcuate segment of the periphery of the through-hole recess.

7. The cold plate according to claim 6, wherein the undercut slot extends from the outer peripheral surface to the fluted region.

8. The cold plate according to claim 5, wherein the fluted region is a first fluted region and wherein the fluted periphery has a plurality of fluted regions.

9. The cold plate according to claim 5, wherein the fluted region is a first fluted region and wherein the fluted periphery has four fluted regions.

10. The cold plate according to claim 5, wherein the through-hole recess defines a first shoulder positioned distally of the fluted periphery.

11. The cold plate according to claim 10, wherein through-hole recess defines a second shoulder positioned distally of the first shoulder and proximally of the opening through the boundary of the passageway defined by the housing wall.

12. The cold plate according to claim 1, wherein the through-hole recess defines a longitudinal axis extending from the aperture in the upper surface of the raised boss to an opposed opening through the boundary of the passageway defined by the housing wall, wherein the cold plate further comprises a spring clip having a leg configured to extend through the undercut slot transversely relative an axis parallel to the longitudinal axis.

13. The cold plate according to claim 12, further comprising a fluid connector having an external surface so complementarily shaped relative to the through-hole recess as to be matingly receivable by the through-hole recess.

14. The cold plate according to claim 13, wherein the fluid connector further defines a distal piston and an annular ring extending circumferentially around the piston proximally positioned of the distal piston.

15. The cold plate according to claim 14, wherein the annular ring is a first annular ring and wherein the fluid connector further defines a second annular ring positioned proximally of and spaced apart from the first annular ring, defining an annular gap positioned therebetween.

16. The cold plate according to claim 15, further comprising an O-ring extending around the piston at a position distally of the first annular ring, wherein the annular gap aligns with the opening defined by the undercut slot when the fluid connector and O-ring are seated within the through-hole recess, wherein the leg of the spring clip extends through the opening defined by the undercut slot and through the annular gap defined by the fluid connector, retaining the fluid connector within the recessed through-hold aperture.

17. The cold plate according to claim 12, wherein the spring clip is a U-shaped spring clip configured to capture the fluid connector within the raised boss defined by the cold plate housing.

18. A cooling system comprising:
a cold plate configured to be placed into thermal contact with a heat-generating component and to facilitate a transfer of heat from the heat-generating component to a fluid passing through the cold plate;
a heat-exchanger configured to reject heat from the fluid to another medium; and
a fluid circuit configured to so circulate the fluid through the cooling system as to convey fluid heated in the cold plate to the heat-exchanger and to convey fluid cooled in the heat-exchanger to the cold plate, wherein the cold plate defines one or more fluid connections for coupling the cold plate with the fluid circuit, wherein at least one of the one or more fluid connections comprises:
a raised boss defining an internal bore, an outer peripheral surface, and an undercut slot extending from the outer peripheral surface to the internal bore;
a fluid connector having a distal portion positioned within the internal bore and a proximal portion extending from the raised boss, the fluid connector defining an external surface having an annular recess aligned with the undercut slot, a shoulder positioned distally of the annular recess and an O-ring positioned distally of the shoulder; and
a retainer clip having an arm extending through the undercut slot and within the annular recess of the fluid connector to capture the distal portion of the fluid connector within the internal bore.

19. The cooling system according to claim 18, wherein the internal bore defines a proximal region having a fluted periphery defining a plurality of fluted regions circumferentially spaced apart from each other, wherein the undercut slot is a first undercut slot that extends from the outer peripheral surface of the raised boss to one of the fluted regions, wherein the raised boss further defines a second undercut slot that extends from the outer peripheral surface of the raised boss to a second one of the fluted regions.

20. The cooling system according to claim 19, wherein the retainer clip is a U-shaped clip having a pair of spaced-apart arms, wherein at least one of the spaced-apart arms is so sized to extend from external to the peripheral wall through the first undercut slot and the second undercut slot.

21. The cooling system according to claim 20, wherein the at least one of the spaced-apart arms defines an inner edge positioned adjacent the external surface of the fluid connector, wherein the inner edge has detente region so configured to urge against the external surface of the fluid connector as to inhibit the U-shaped clip from backing out of the first undercut slot and the second undercut slot.

22. configured to be positioned adjacent the second shoulder an annular ring configured to seat against the first shoulder when the fluid connector is positioned within.

23. Wherein the fluid connector further defines a proximal shoulder position approximately of the annular ring and spaced apart there from.

24. Wherein the spring clip it's sized to pass laterally transversely through the annular slot when the fluid connector is positioned in the aperture and the spring clip extends through the undercut slots.new line

25. Wherein the fluid connector further defines a cylindrical portion extending distally of the annular ring, further defines an o-ring extending around the cylindrical portion.

26. Wherein the second shoulder of the aperture is sized to receive the o-ring in a ceiling engagement when the fluid connector and o-ring assembly is positioned within the aperture and retained therein by the spring clip.
